(19) United States
(12) Patent Application Publication
(10) Pub. No.: US 2015/0372159 A1
(43) Pub. Date: Dec. 24, 2015

(54) SYSTEMS AND METHODS FOR GRAPHENE PHOTODETECTORS

(71) Applicant: The Trustees Of Columbia University In The City Of New York, New York, NY (US)

(72) Inventors: DIRK ENGLUND, New York, NY (US); Ren-Jye Shiue, Cambridge, MA (US); Xuetao Gan, Cambridge, MA (US)

(73) Assignee: The Trustees Of Columbia University In The City Of New York, New York, NY (US)

(21) Appl. No.: 14/731,874

(22) Filed: Jun. 5, 2015

Related U.S. Application Data
(63) Continuation of application No. PCT/US2013/073613, filed on Dec. 6, 2013.
(60) Provisional application No. 61/734,661, filed on Dec. 7, 2012.
(60) Provisional application No. 61/735,366, filed on Dec. 10, 2012.

(51) Int. Cl. H01L 31/028; H01L 31/18; G01J 3/18; G01J 3/28; G01J 3/14; H01L 31/112; H01L 27/144

(52) U.S. Cl. CPC H01L 31/028; H01L 31/1126; H01L 31/1804; H01L 27/1443; H01L 27/1446; G01J 3/2803; G01J 3/14; G01J 3/1809; G01J 2003/2813

(57) ABSTRACT

Systems and methods for graphene photodetectors are disclosed herein. A device for detecting photons can include a waveguide and at least one graphene layer disposed proximate to the waveguide. An insulating layer can be disposed between the waveguide and the graphene layer. A first electrode can be connected to a first end of the graphene layer, and a second electrode can be connected to a second end of the graphene layer opposite the first end.

### CROSS REFERENCE TO RELATED APPLICATION

This application is a continuation of International Patent Application Serial No. PCT/US2013/073613, filed Dec. 6, 2013 and claims priority from U.S. Provisional Application Ser. No. 61/734,661, filed Dec. 7, 2012, and U.S. Provisional Application Ser. No. 61/735,366, filed Dec. 10, 2012, the disclosures of which are incorporated by reference herein.

### STATEMENT REGARDING FEDERALLY SPONSORED RESEARCH

This invention was made with government support under Grant No. W911NF-10-1-0416, awarded by the Army Research office/DARPA, and Presidential Early Career Award for Scientists and Engineers (PECASE), awarded by the Air Force Office of Scientific Research (AFOSR). The government has certain rights in the invention.

### BACKGROUND

The disclosed subject matter relates to systems and methods for graphene photodetectors.

Photodetection with wavelength resolving power can be used in a range of applications from communications to spectroscopy. However, certain photodetectors can be based on semiconductors, and their operation spectral range can be limited by the semiconductor bandgap. This bandgap can be nearly static (a small change can occur with direct current (DC) stark shifting). The bandgap can be unavailable for certain optical wavelengths, for example, in the mid- to deep-infrared.

Graphene, a single-atomic layer material of carbon, can have an absorbance, for example, of about 2.3% in the spectral range from 400 nm to 7 μm, and this absorbance can be due to the linear dispersion electronic structure of graphene. The absorbance over this spectral range can enable photodetection with graphene to have a flat responsivity over a broader spectral range than with certain other materials. Graphene can have high carrier transport velocity, e.g., a carrier transport velocity of 1×10⁶ to 2.5×10⁶ m/s, even under a moderate electrical field. As such, an internal electrical field can be built by a potential difference on graphene to allow fast and efficient photodetection, for example, a carrier transient time smaller than 1 ps for a ballistic distance of 1 μm, supporting a speed of 1 THz for efficient photodetection with zero-bias operation.

For example, graphene can demonstrate ultrafast carrier dynamics, for example, about 1-2 ps, for both electrons and holes, and a weak internal electric field can allow relatively high-speed and efficient photocarrier separation. Moreover, graphene's two-dimensional nature can enable the generation of multiple electron-hole pairs for high-energy photon excitation, for example, photon excitation energy from 0.16 eV to 4.65 eV. This carrier multiplication process can result in inherent gain in graphene photodetection, existing even without external bias, unlike certain avalanche detection techniques. Despite these features, the low optical absorption in graphene can result in low photoresponsivity in vertical-incidence photodetector designs.

While the internal electrical field can allow a high internal quantum efficiency, for example, from 15 to 30%, the coupling between the single-pass light and the thin graphene layer can be inefficient in a normal incident configuration, for example, limiting the photodetection responsivity in the order of 0.001 A/W. High responsivity can be used for certain applications of ultrafast graphene photodetectors. Graphene can be integrated with nano-, micro-cavities, and surface plasmon polariton to improve the external quantum efficiency of a graphene photodetector over a narrow resonant spectral range.

There is a need for improved techniques for graphene photodetectors.

### SUMMARY

Systems and methods for graphene photodetectors are disclosed herein.

In one aspect of the disclosed subject matter, exemplary devices for detecting photons including a waveguide and at least one graphene layer disposed proximate to the waveguide are disclosed. An insulating layer can be disposed between the waveguide and the graphene layer. A first electrode can be connected to a first end of the graphene layer, and a second electrode can be connected to a second end of the graphene layer opposite the first end.

In some embodiments, the waveguide can be a silicon waveguide. For example, the silicon waveguide can have a cross-section of 220 nm by 520 nm. Additionally or alternatively, the insulating layer can include at least one of a silicon dioxide layer, a boron nitride layer, or a hafnium oxide layer. For example, the insulating layer can be a silicon dioxide layer having a thickness of 10 nm.

In some embodiments, the graphene layer can be a graphene bi-layer. For purpose of illustration and not limitation, the graphene bi-layer can have a length of at least 10 μm. For example, the graphene bi-layer can have a length of 53 μm. Additionally or alternatively, the first electrode can be a first distance from the waveguide and the second electrode can be a second distance from the waveguide. In some embodiments, the second distance can be less than the first distance. For purpose of illustration and not limitation, the second distance can be less than 1 μm, and the first distance can be greater than 3 μm. For example, the second distance can be 100 nm, and the first distance can be 3.5 μm.

The at least one graphene layer can include a metal-doped junction proximate to the second electrode. For purpose of illustration and not limitation, the metal-doped junction can have a width up to 0.9 μm. For example, the metal-doped junction can have a width of 200-500 nm. Additionally or alternatively, the first electrode and second electrode each can be a titanium/gold ( 1/40 nm) metal electrode.

In some embodiments, at least one of a voltage source or a current source can be connected to the first electrode. Additionally or alternatively, a light source can be coupled to the waveguide. For purpose of illustration and not limitation, the light source can be a laser. For example, the laser can have a wavelength of 1450-1590 nm.

In some embodiments, at least one coupler can be coupled to the waveguide. For example, the coupler(s) can include at least one of an optical fiber, a lensed optical fiber, a lens, an edge coupler, an evanescent coupler, a grating coupler, or a butt-coupler. Additionally or alternatively, a spectral selection mechanism can direct a selected frequency component of electromagnetic radiation to the graphene layer. For example, the spectral selection mechanism can include at least one of a superprism, a drop-cavity filter, an echelle grating, or a scannable interface filter. Additionally or alternatively, a gate electrode can be disposed proximate to the at least one graphene layer, and a voltage source can be connected to the gate electrode to modulate a Fermi energy E_{G} of the graphene layer to block absorption of a selected frequency ω of electromagnetic radiation.

In another aspect of the disclosed subject matter, methods of making a device for detecting photons using a silicon-on-insulator wafer are disclosed. In one example, a waveguide can be formed on the silicon-on-insulator wafer. An insulating layer can be deposited onto the waveguide. At least one graphene layer can be deposited onto the insulating layer. A first electrode and a second electrode can be deposited, the first electrode deposited at a first end of the graphene layer and the second electrode deposited at a second end of the graphene layer.

In some embodiments, the silicon-on-insulator wafer can include a silicon layer disposed on a buried oxide (BOX) layer. For purpose of illustration and not limitation, the BOX layer can include a silicon dioxide layer having a thickness of 2 μm, and the silicon layer can have a thickness of 220 nm. Additionally or alternatively, the waveguide can be formed on the silicon-on-insulator wafer by electron beam lithography and/or inductively coupled plasma (ICP) dry etching.

In some embodiments, a coupler can be coupled to the waveguide. For purpose of illustration and not limitation, at least one of an optical fiber, a lensed optical fiber, a lens, or a butt-coupler can be coupled to the waveguide. For example, a butt-coupler can be fabricated on at least one end of the waveguide. Additionally or alternatively, the insulating layer can be deposited onto the waveguide and the silicon-on-insulator wafer and planarized by chemical mechanical polishing (CMP).

In some embodiments, a mechanically exfoliated graphene bi-layer can be deposited. Additionally or alternatively, the first electrode and the second electrode can be deposited by depositing a first resist at the first end of the at least one graphene layer and a second resist at the second end of the at least one graphene layer. A shape of the first electrode can be defined in the first resist, and a shape of the second electrode can be defined in the second resist. Metal can be deposited into the first resist to form the first electrode and into the second resist to form the second electrode. The first and second resists can be removed.

In another aspect of the disclosed subject matter, a device for spectroscopy can include at least one input waveguide. At least one coupler can be coupled to the at least one input waveguide. A spectral separation mechanism can be coupled to the at least one input waveguide to separate the spectral components of electromagnetic radiation. A plurality of photodetectors can be disposed proximate to the spectral separation mechanism, each configured to detect a respective selected frequency component of electromagnetic radiation, and each of the photodetectors having graphene as the photodetecting layer.

In some embodiments, the coupler(s) can include at least one of an optical fiber, a lensed optical fiber, a lens, an edge coupler, an evanescent coupler, a grating coupler, or a butt-coupler. Additionally or alternatively, the spectral separation mechanism can include at least one of a superprism, a drop-cavity filter, or an echelle grating. For example, the spectral separation mechanism can include a superprism, and a plurality of waveguides can be coupled to the superprism to direct the respective selected frequency component of electromagnetic radiation to each of the photodetectors. Additionally or alternatively, the spectral separation mechanism can include a plurality of drop-cavity filters, and each of photodetectors can be integrated on a respective one of the drop-cavity filters corresponding to the respective selected frequency component of electromagnetic radiation thereof.

In some embodiments, the respective selected frequency component of electromagnetic radiation of each of the photodetectors can be different than the respective selected frequency component of electromagnetic radiation of each of the other photodetectors.

In another aspect of the disclosed subject matter, devices for detecting a selected wavelength of electromagnetic radiation are disclosed. Exemplary devices can include a scannable interface filter having at least one cavity. The cavity can have a resonant wavelength to match the selected wavelength. At least one photodetector can be disposed within the cavity, and the photodetector can have graphene as the photodetecting layer to detect the selected wavelength of electromagnetic radiation.

In some embodiments, an actuation mechanism can be connected to the scannable interface filter to adjust the resonant wavelength of the cavity. For example, the actuation mechanism can include at least one of a piezoelectric actuation mechanism, a static electric actuation mechanism, and a electrostrictive actuation mechanism.

For purpose of illustration and not limitation, the scannable interface filter can include a first mirror having a first reflectivity and a second mirror having a second reflectivity, and the cavity can be between the first and second mirrors. The first reflectivity can be greater than the second reflectivity. In some embodiments, the scannable interface filter can include at least one further mirror. A further cavity can be between the second mirror and the further mirror. Additionally or alternatively, the scannable interface filter can include a plurality of mirrors. A further cavity can be between the second mirror and the plurality of mirrors, and the plurality of mirrors can include a plurality of cavities between successive ones of the plurality of mirrors.

In some embodiments, the at least one photodetector can be a two-dimensional array of photodetectors.

In another aspect of the disclosed subject matter, devices for detecting photons, which include at least one graphene layer, are disclosed. In one example, a source electrode can be connected to a first end of the graphene layer, and a drain electrode can be connected to a second end of the graphene layer opposite the first end. A gate electrode can be proximate to the at least one graphene layer, and a voltage source can be connected to the gate electrode and configured to modulate a Fermi energy E_{G} of the at least one graphene layer to block absorption of a selected frequency ω of electromagnetic radiation.

In some embodiments, the voltage source can be configured to modulate the Fermi energy E_{G} to greater than hω/2. Additionally or alternatively, a waveguide can be disposed proximate to the graphene layer and configured to direct electromagnetic radiation to the graphene layer. Additionally or alternatively, an insulating layer can be disposed between the waveguide and the graphene layer.

In some embodiments, a spectral selection mechanism can direct a selected frequency component of electromagnetic radiation to the at least one graphene layer. For example, the spectral selection mechanism can include at least one of a superprism, a drop-cavity filter, an echelle grating, or a scannable interface filter.

In another aspect of the disclosed subject matter, methods for detecting electromagnetic radiation are disclosed. In an exemplary embodiment, a method can use a device for detecting photons having at least one graphene layer, a source electrode connected to a first end of the graphene layer, a drain electrode connected to a second end of the graphene layer opposite the first end, and a gate electrode proximate to the graphene layer. The method can include directing electromagnetic radiation to the at least one graphene layer. A gate voltage at the gate electrode can be modulated to modulate a Fermi energy E_{G} of the at least one graphene layer to block absorption of at least one frequency ω of a spectrum of frequencies ω(E_{G}) of the electromagnetic radiation. A photocurrent I can be detected between the source electrode and drain electrode.

In some embodiments, the gate voltage can be modulated to modulate the Fermi energy E_{G} to greater than hω/2. Additionally or alternatively, the modulating and detecting can be repeated for each frequency in the spectrum of frequencies ω(EG). The photocurrent I(E_{G}) can be recorded as a function of Fermi energy E_{G}. In some embodiments, the power spectrum P(ω) can be calculated based on the photocurrent I(E_{G}) and the spectrum of frequencies ω(E_{G}).

The accompanying drawings, which are incorporated and constitute part of this disclosure, illustrate embodiments of the disclosed subject matter and serve to explain the principles of the disclosed subject matter.

### BRIEF DESCRIPTION OF THE DRAWINGS

FIG. 1A shows a schematic illustration of an exemplary device for detecting photons, in accordance with some embodiments of the disclosed subject matter.

FIG. 1B displays an optical microscope image of an exemplary photodetector device, in accordance with some embodiments of the disclosed subject matter.

FIG. 1C displays a scanning electron microscope image of an exemplary photodetector device, in accordance with some embodiments of the disclosed subject matter.

FIG. 1D shows a schematic illustration of an exemplary device for detecting photons, in accordance with some embodiments of the disclosed subject matter.

FIG. 1E depicts a cross-section view of an exemplary device for detecting photons, in accordance with some embodiments of the disclosed subject matter.

FIG. 1F displays an optical microscope image of an exemplary photodetector device, in accordance with some embodiments of the disclosed subject matter.

FIG. 1G displays a scanning electron microscope image of an exemplary photodetector device, in accordance with some embodiments of the disclosed subject matter.

FIG. 1H shows a schematic illustration of an exemplary device for detecting photons, in accordance with some embodiments of the disclosed subject matter.

FIG. 1I depicts a cross-section view of an exemplary device for detecting photons, in accordance with some embodiments of the disclosed subject matter.

FIG. 1J displays an optical microscope image of an exemplary photodetector device, in accordance with some embodiments of the disclosed subject matter.

FIG. 1K displays a scanning electron microscope image of an exemplary photodetector device, in accordance with some embodiments of the disclosed subject matter.

FIG. 2A shows a scanning photocurrent image of an exemplary device 100 measured on a vertical confocal microscope setup with a normal incidence, in accordance with some embodiments of the disclosed subject matter.

FIG. 2B shows the corresponding scanning optical reflection image of the exemplary device 100, in accordance with some embodiments of the disclosed subject matter.

FIG. 2C shows an SEM image of the corresponding measured section of the exemplary device 100, indicating the positions of the waveguide 111, first metal electrode 121, and second metal electrode 122, in accordance with some embodiments of the disclosed subject matter.

FIG. 2D shows a spatial resolved photocurrent image of an exemplary device 101 obtained at zero source-drain voltage and a laser power of 1.5 mW, in accordance with some embodiments of the disclosed subject matter.

FIG. 2E shows a corresponding optical reflection image measured on a vertical confocal microscope setup with a normal incidence of the exemplary device 101, in accordance with some embodiments of the disclosed subject matter.

FIG. 2F shows an SEM image of the corresponding measured section of the exemplary device 101, indicating the positions of the waveguide 111 and first and second metal electrodes 121, 122, in accordance with some embodiments of the disclosed subject matter.

FIG. 2G shows a plot of the bias dependence of the photodetection on graphene later 131 excited by light coupled from the waveguide 111 through its evanescent field, in accordance with some embodiments of the disclosed subject matter.

FIG. 2H shows the a plot of photoresponsivity of the exemplary device 101 with light transmitting in the waveguide 111 respective to the excitation wavelength, in accordance with some embodiments of the disclosed subject matter.

FIG. 2I shows a scanning reflection image of an exemplary device 102, indicating the edges of the metal electrodes, in accordance with some embodiments of the disclosed subject matter.

FIG. 2J shows an SEM image of the measured section of the exemplary device 102, in accordance with some embodiments of the disclosed subject matter.

FIG. 2K shows a spatially resolved photocurrent (amplitude) image of the exemplary device 102 measured at zero bias voltage and representing two photocurrent strips around the metal/graphene junctions, in accordance with some embodiments of the disclosed subject matter.

FIG. 3A shows an image of a simulated exemplary device 100, in accordance with some embodiments of the disclosed subject matter.

FIG. 3B shows a plot of the responsivity versus source-drain bias voltage of the exemplary device 100, in accordance with some embodiments of the disclosed subject matter.

FIG. 3C shows a plot of the photoresponsivity of the exemplary device 100 as a function of the excited wavelength from 1450 nm to 1590 nm, in accordance with some embodiments of the disclosed subject matter.

FIG. 3D shows a plot of photocurrent of the exemplary device 100 as a function of the incident power from a pulsed laser, in accordance with some embodiments of the disclosed subject matter.

FIG. 3E shows a plot of dynamic opto-electrical response of an exemplary device 101, in accordance with some embodiments of the disclosed subject matter.

FIG. 3F shows a plot of responsivity of the exemplary device 101 as a function of the incident power, in accordance with some embodiments of the disclosed subject matter.

FIG. 3G shows, at the top, a simulated potential profile (black solid line) across the graphene channel of an exemplary device 102, in accordance with some embodiments of the disclosed subject matter.

FIG. 3H shows a plot of the detected photocurrent (Iₚₕₒₜₒ) as a function of incident power (Pᵢₙₚᵤₜ) obtained at zero bias voltage (V_{B}=0), in accordance with some embodiments of the disclosed subject matter.

FIG. 3I shows the responsivity as a function of bias voltage of the exemplary device 102, in accordance with some embodiments of the disclosed subject matter.

FIG. 3J shows the broadband, uniform responsivity of the exemplary device 102 over a wavelength range from 1450 nm to 1590 nm at zero bias, in accordance with some embodiments of the disclosed subject matter.

FIG. 4A shows a plot of the alternating current (AC) photoresponse of an exemplary device 100 with zero bias voltage as a function of frequency, in accordance with some embodiments of the disclosed subject matter.

FIG. 4B displays the AC photoresponse of the device at zero bias, showing about 1 dB degradation of the signal at 20 GHz, in accordance with some embodiments of the disclosed subject matter.

FIG. 5 shows a flowchart of an exemplary method for making a device for detecting photons, in accordance with some embodiments of the disclosed subject matter.

FIG. 6 shows a diagram of an exemplary graphene photodetector, in accordance with some embodiments of the disclosed subject matter.

FIGS. 7A and 7B show diagrams of potential difference across exemplary graphene photodetectors, in accordance with some embodiments of the disclosed subject matter.

FIG. 8 shows a diagram of exemplary on-chip graphene spectrometer, in accordance with some embodiments of the disclosed subject matter.

FIG. 9 shows a diagram of exemplary on-chip graphene spectrometer, in accordance with some embodiments of the disclosed subject matter.

FIG. 10 shows a diagram of an exemplary device for detecting a selected wavelength of electromagnetic radiation, in accordance with some embodiments of the disclosed subject matter.

FIG. 11 shows a schematic illustration of an exemplary device for detecting photons including a gate electrode, in accordance with some embodiments of the disclosed subject matter.

FIG. 12A shows a schematic illustration of an exemplary device for detecting photons, in accordance with some embodiments of the disclosed subject matter.

FIG. 12B displays a scanning electron microscope image of an exemplary photodetector device, in accordance with some embodiments of the disclosed subject matter.

FIG. 12C displays an optical microscope image of an exemplary photodetector device, in accordance with some embodiments of the disclosed subject matter.

FIG. 13 shows a flowchart of an exemplary method for detecting electromagnetic radiation, in accordance with some embodiments of the disclosed subject matter.

FIG. 14A shows a diagram of an exemplary device for detecting photons, in accordance with some embodiments of the disclosed subject matter.

FIG. 14B shows a diagram of an exemplary ring-oscillator integrated graphene photodetector and modulator architecture, in accordance with some embodiments of the disclosed subject matter.

FIG. 14C shows a diagram of a photonic crystal modulator and photodetector architecture, in accordance with some embodiments of the disclosed subject matter.

Throughout the drawings, the same reference numerals and characters, unless otherwise stated, are used to denote like features, elements, components or portions of the illustrated embodiments. Moreover, while the present disclosed subject matter will now be described in detail with reference to the FIGS., it is done so in connection with the illustrative embodiments.

### DETAILED DESCRIPTION

Techniques for graphene photodetectors are presented. An exemplary device for detecting photons can include a waveguide. At least one graphene layer can be disposed proximate to the waveguide, and an insulating layer can be disposed between the waveguide and the at least one graphene layer. A first electrode can be connected to a first end of the graphene layer, and a second electrode can be connected to a second end of the graphene layer opposite the first end.

The electronic structure of graphene can be unique, resulting in physical and optical properties that can enhance performance of certain opto-electronic devices. For purpose of illustration and not limitation, physical and optical properties of graphene-based photodetectors can include an ultra-fast response, for example, up to 1 THz, across a broad spectrum, for example, from 400 nm to 15 μm or from visible to mid infrared, a linear dispersion electric structure without a bandgap, a strong electron-electron interaction, and photocarrier multiplication, as discussed further below. For example, photodetectors based on graphene can display ultrafast response with zero-bias operation over a broad spectral range. The optical absorption of the graphene and/or interaction between the atomic-layer graphene and the single-pass light can be weak and can limit the responsivity of photodetection, for example, about three orders of magnitude lower than certain other photodetectors. Graphene can be integrated into nanocavities, microcavities and plasmon resonators to enhance interaction and/or absorption, but these approaches can restrict photodetection to narrow bands. Hybrid graphene-quantum dot architectures can improve responsivity, but these architectures can limit response speed.

Graphene can be coupled to a bus waveguide to enhance light absorption over a broadband spectrum. In some aspects of the disclosed subject matter, and as discussed further below, graphene photodetector can be integrated onto a waveguide, for example, a silicon-on-insulator (SOI) bus waveguide, and this integration can enhance graphene absorption and the corresponding photo-detection efficiency with high speed over a broad spectral bandwidth.

For purpose of illustration, and as discussed further below, at least one layer of graphene can be deposited on top of a waveguide, for example a silicon waveguide, to extend its interaction with light and improve the light-harvesting of graphene over a broad spectral range.

In another aspect of the disclosed subject matter, and as discussed further below, graphene photodetectors can be used in spectrometers to achieve high spectral resolution across a wide wavelength region, for example, a wavelength region spanning from the visible into the deep infrared spectrum. The detector(s) in the device can be based on graphene. Graphene can produce uniform photodetection from the visible into the deep infrared spectrum, for example, a uniform photoresponse from 400 nm to 7 μm, a higher photoresponse for wavelengths less than 400 nm, and a decreased photoresponse (e.g. about half) for wavelengths greater than 7 μm.

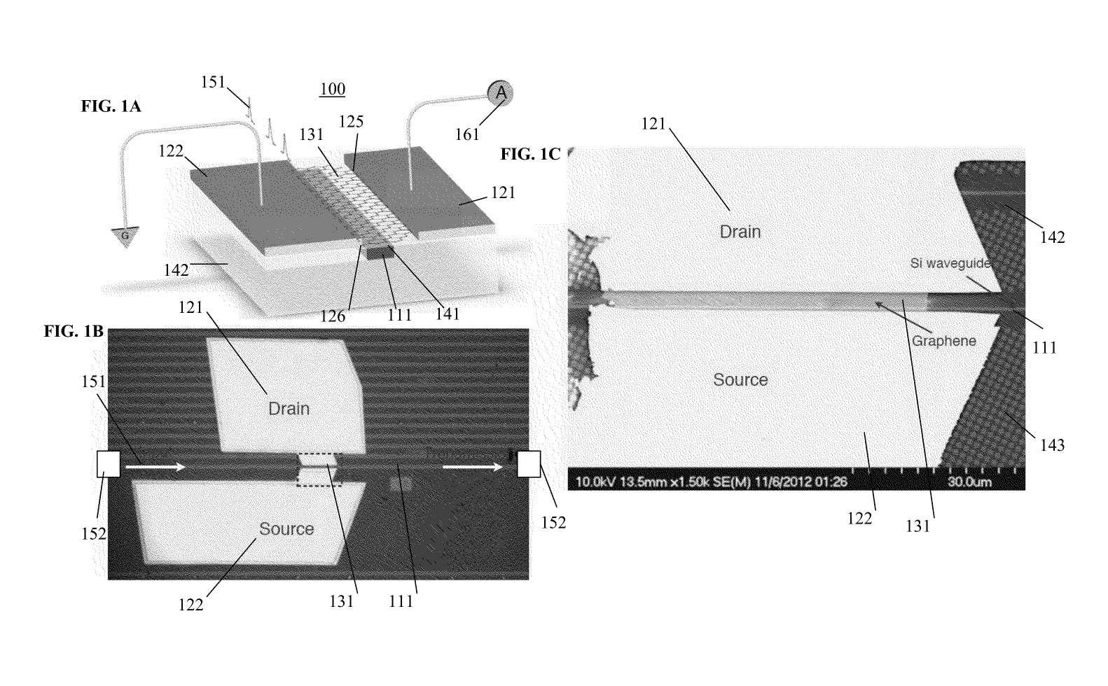

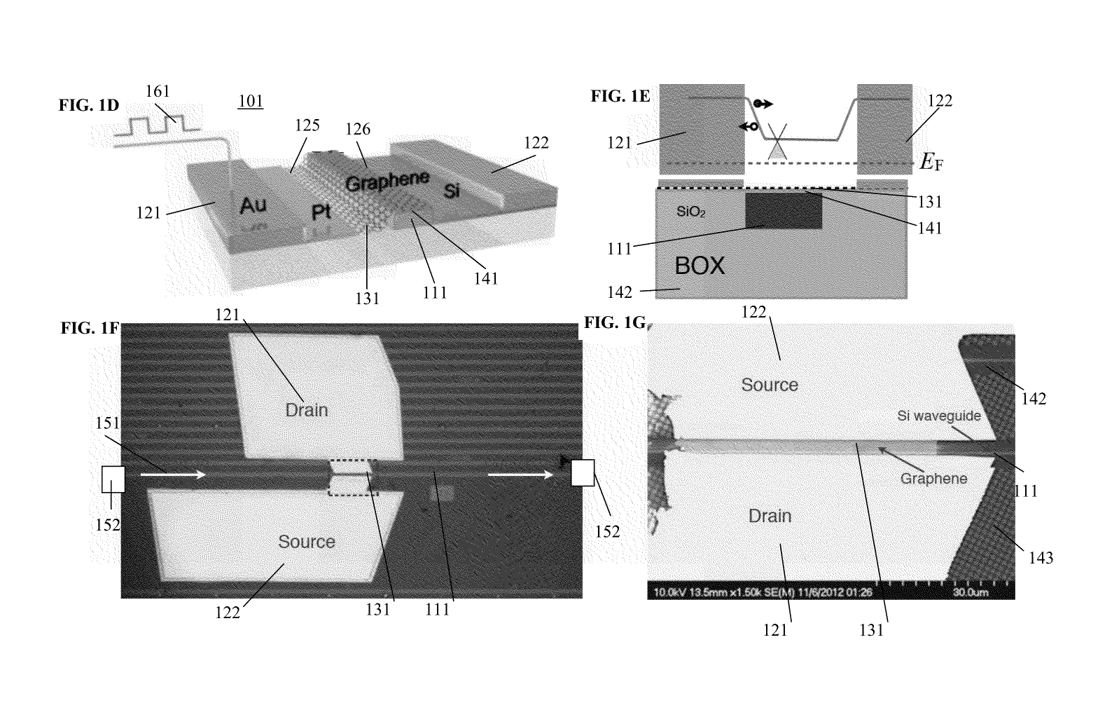

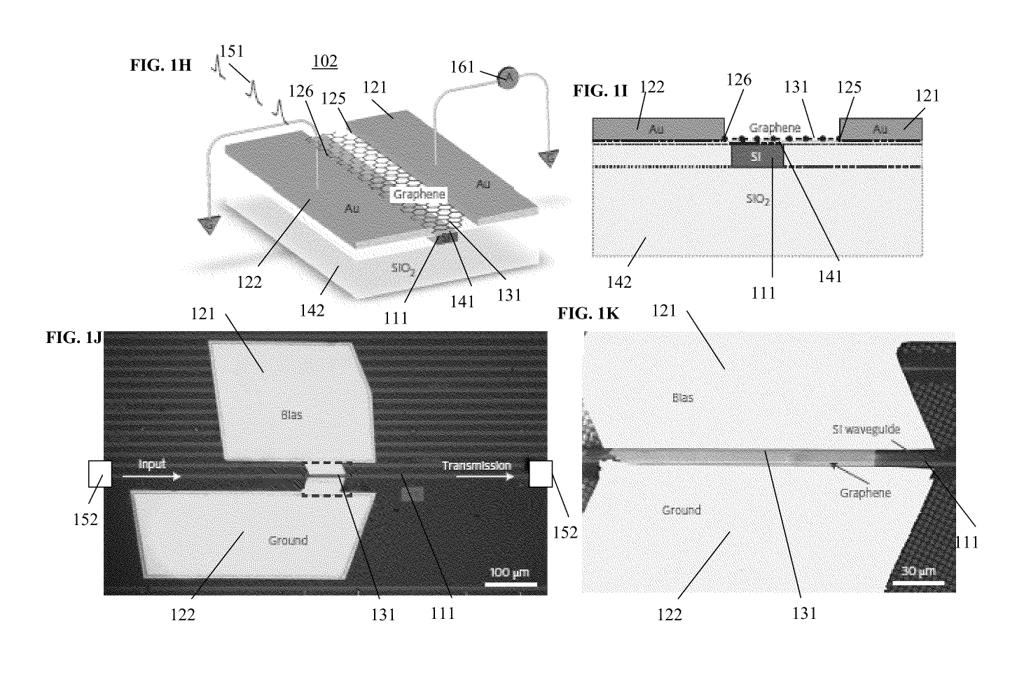

Referring to FIG. 1A, an exemplary device 100 for detecting photons can include a waveguide 111. In some embodiments, the waveguide 111 can be disposed on a substrate 142. For purpose of illustration and not limitation, the waveguide 111 can be any suitable optical waveguide, for example, an optical waveguide with an evanescent field, such as a silicon waveguide or a waveguide made of any other suitable materials transparent at the wavelength of interest. The waveguide 111 can have any suitable dimensions. For purpose of illustration and not limitation, the waveguide 111 can be cross-sectional area such that a single mode pattern of light propagates in the waveguide 111. Alternatively, the waveguide 111 can have a larger cross-sectional area to allow for multimode operation, for example, twice as large as a single-mode waveguide 111. Multimode waveguides 111 can enhance efficiency of coupling between the waveguide 111 and graphene 131, for example, because there can be more than one mode for coupling. For example, as embodied herein, a single-mode silicon waveguide 111 can have a cross-section of 220 nm by 520 nm. For purpose of illustration, a silicon bus waveguide 111 can be fabricated on a silicon-on-insulator wafer with a cross-section of 220 nm by 520 nm, as described further below, to confine light in a sub-wavelength dimension.

At least one graphene layer 131 can be disposed proximate to the waveguide 111. For purpose of illustration and not limitation, the graphene layer 131 can absorb light 151 by coupling with the evanescent field of the waveguide 111 mode and can generate photocarriers. In some embodiments, the at least one graphene layer 131 can be a graphene bi-layer 131. Single- or bi-layer graphene 131 can have any suitable dimensions. Increasing the length of the graphene layer(s) 131 can increase the interaction between the evanescent field of the waveguide 111 and the graphene layers 131 to increase absorption in the graphene layer(s) 131. For purpose of illustration and not limitation, the length of a graphene layer 131 can be 10 μm or more. For example, a graphene bi-layer 131 can have a length of 53 μm.

In some embodiments, an insulating layer 141 can be disposed between the waveguide and the at least one graphene layer. The insulating layer 141 can isolate the graphene layer 131 from the waveguide 111, for example, by preventing electrical contact between the graphene layer 131 and the waveguide 111. The insulating layer 141 can be any material suitable to electrically isolate the graphene layer 131 from the waveguide 111. For example, the insulating layer 141 can include a silicon dioxide layer, a hafnium oxide layer, a boron nitride layer, and/or a layer of any other suitable dielectric insulator.

The insulating layer 141 can have any suitable thickness to allow evanescent coupling between the waveguide 111 and the graphene layer 131. For purpose of illustration and not limitation, the thickness of the insulating layer 141 can be less than the penetration depth of the material of the insulating layer 141, where the penetration depth can be how far light of the desired wavelength can penetrate the medium such as about 1 wavelength in the medium. In practice, an insulating layer 141 can be have a thickness of less than 100 nm. For example, a silicon dioxide insulating layer 141 can have a thickness of 10 nm.

For purpose of illustration, and as described further below, the insulating layer 141 can be deposited on the waveguide 111 and the substrate 142. The insulating layer can be planarized before the graphene layer 131 are deposited thereon. A planar insulating layer 141 disposed between the graphene layer 131 and the waveguide 111 can avoid fragmentation of the graphene layer 131 at the edge of the waveguide 111.

A first electrode 121 can be connected to a first end of the graphene layer 131, and a second electrode 122 can be connected to a second end of the graphene layer 131 opposite the first end. In some embodiments, the first electrode 121 can be a first distance from the waveguide 111 and the second electrode 122 can be a second distance from the waveguide 111. The first and second distances can each be any suitable distance. For purpose of illustration and not limitation, the first distance can be less than the second distance. Alternatively, the second distance can be less than the first distance. In either case, when the first distance is different than the second distance, a potential different or electric field can be created across the graphene layer 131, as described further below. For purpose of illustration and not limitation, the second distance can be less than 1 μm, e.g., 100 nm, and the first distance can be greater than 3 μm, e.g., 3.5-5.0 μm.

The first end of the graphene layer 131 can include a first metal-doped junction 125 proximate to the first electrode 121. The first metal-doped junction 125 can increase the potential difference or electric field strength in the graphene layer 131, for example, due to a work function mismatch between graphene and metal. The metal doping can be any suitable metal, including but not limited to platinum, gold, aluminum, titanium/gold, or chrome/gold. Additionally or alternatively, the second end of the graphene layer 131 can include a second metal-doped junction 126 proximate to the second electrode 122. For purpose of illustration and not limitation, the first metal-doped junction 125 and/or the second metal doped junction 126 each can have any suitable width, such as a width up to 0.9 μm. For example, the first metal-doped junction 125 and/or the second metal doped junction 126 each can have a width of 200-500 nm.

For purpose of illustration and not limitation, a second electrode 122 can be closer to the waveguide 111 than the first electrode 121. Due to the metal-doped junction 126, there can be a potential difference at the metal/graphene interface. This potential difference can establish an internal electric field along the graphene layer 131 and can overlap with the photocarriers, which can be photon-excited electron-hole pairs generated in the graphene layer 131 by absorption of photons. This potential difference can separate the photocarriers and form a photocurrent on the graphene layer 131. The photocurrent of the separated photocarriers can be measured across the first electrode 121 and the second electrode 122.

The first electrode 121 and the second electrode 122 each can be made of any suitable material or materials, for example, any suitable metal or conductor. For purpose of illustration and not limitation, the first electrode 121 and second electrode 122 each can be a gold electrode or a titanium/gold metal electrode. The first electrode 121 and the second electrode 122 each can have any suitable dimensions. For example, the first electrode 121 and the second electrode 122 each can have a thickness of 20 nm to 200 nm. For purpose of illustration and not limitation, the first electrode 121 and second electrode 122 each can be a gold electrode with a thickness of 40 nm. Alternatively, the first electrode 121 and second electrode 122 each can be a titanium/gold metal electrode having a thickness of 1/40 nm, i.e. a titanium layer of thickness 1 nm with a gold layer of thickness 40 nm disposed thereon.

For purpose of illustration and not limitation, the optical mode from the waveguide 111 can couple to the graphene layer 131 through the evanescent field, leading to optical absorption and the generation of photocarriers. The first electrode 121 and second electrode 122 can be located on opposite sides of the waveguide 111 and contacted to the graphene layer 131 to collect the photocurrent from the graphene layer 132. One of these electrodes, for example the second electrode 122, can be positioned about 100 nm from the edge of the waveguide 111 to create a lateral metal-doped junction 126 that overlaps with the waveguide mode. In some embodiments, the junction 126 can be close enough to the waveguide 111 to efficiently separate the photo-excited electron-hole pairs at zero bias, but the separation between the junction 126 and waveguide 111 can be large enough to ensure that the optical absorption is dominated by graphene layer 131 to limit optical absorption and to limit optical absorption by the second electrode 122.

FIG. 1B displays an optical microscope image of an exemplary photodetector device, in accordance with some embodiments of the disclosed subject matter. A 53 μm long, mechanically exfoliated graphene bi-layer 131, which can be confirmed by a micro-Raman spectroscopy, can be transferred onto the waveguide 111, for example, using a precise transfer technique such as described in commonly assigned International Application No. PCT/US2013/061633, filed Sep. 25, 2013, titled “Micro-Device Transfer for Hybrid Photonic and Electronic Integration Using Polydimethylsiloxane Probes,” the disclosure of which is incorporated by reference herein. Additionally or alternatively, the graphene layer(s) 131 can be transferred using the transfer techniques described in C. R. Dean et al., Boron nitride substrates for high-quality graphene electronics, Nature Nanotechnology 5, 722-726 (2010), available at http://www.nature.com/nnano/journal/v5/n10/full/nnano.2010.172.html, which is incorporated by reference herein. Electromagnetic radiation 151, e.g. light 151, can transmit along the waveguide 111 and couple with the graphene layers 131 through its evanescent field. First electrode 121 and second electrode 122, each of which can be titanium/gold ( 1/40 nm) metal electrodes, can be drain and source electrode, respectively, and can be deposited on the graphene layer at both sides of the waveguide asymmetrically, as discussed herein, for example, using electron beam lithography and evaporation. One of the electrodes, for example, the second electrode 122, can be closer to the waveguide 111, for example, at a second distance of about 100 nm, which can be confirmed using a scanning electron microscope (SEM) image of the device. FIG. 1C displays a scanning electron microscope image of an exemplary photodetector device, in accordance with some embodiments of the disclosed subject matter. As shown in FIG. 1C, the first electrode 121 can be at a first distance from the waveguide 111, for example, about 3.5 μm from the waveguide 111. The SEM image also displays a planarized platform, for example, insulating layer 141, that can enable conformal contacts between the graphene layer 131, the waveguide 111, the first electrode 121, and the second electrode 122. The first electrode 121 and second electrode 122 can conduct the photocurrent across the graphene bi-layer 131. A graphene bi-layer 131 can provide about twice the absorption as a graphene single layer.

FIG. 1D shows a schematic illustration of an exemplary device 101 for detecting photons, in accordance with some embodiments of the disclosed subject matter. A graphene layer 131 can be transferred onto a planarized waveguide 111 and can be contacted to first electrode 121 and second electrode 122. One of the electrodes, for example first electrode 121, can be closer to the waveguide 111 to create a potential difference on the graphene layer 131. A silicon waveguide 111 and graphene layer 131 can be electrically isolated by an insulating layer 141, for example, a 10 nm thick layer of silicon oxide.

FIG. 1E depicts a cross-section view of an exemplary device for detecting photons overlapped with the optical field for the transversal electrical-like waveguiding mode, calculated by the finite element simulation, in accordance with some embodiments of the disclosed subject matter. The finite element simulations are discussed further below. FIG. 1F displays an optical microscope image of an exemplary photodetector device, in accordance with some embodiments of the disclosed subject matter. The light 151 can be coupled in and out of the waveguide 111 through any suitable coupler 152, as discussed further below. For purpose of illustration and not limitation, a polymer coupler, such as an SU8 butt-coupler or evanescent coupler, can be placed at each of two ends of the waveguide 111, and an optical fiber, such as a lensed optical fiber, can be coupled to each polymer coupler. FIG. 1G displays a scanning electron microscope image of an exemplary photodetector device, in accordance with some embodiments of the disclosed subject matter. As shown in FIG. 1G, the first distance between the first electrode 121 and the waveguide 111 can be about 100 nm. The graphene layer 131 covering on the waveguide 111 can be about 53 μm long.

FIG. 1H shows a schematic illustration of an exemplary device 102 for detecting photons, and FIG. 1I depicts a cross-section view of an exemplary device for detecting photons, in accordance with some embodiments of the disclosed subject matter. For purpose of illustration and not limitation, a silicon bus waveguide 111 can be fabricated on an silicon-on-insulator (SOI) wafer and cab be planarized using SiO₂. A graphene layer 131 can be transferred onto a planarized waveguide 111 and can be contacted to first electrode 121 and second electrode 122. The first electrode 121 and second electrode 122 can conduct the generated photocurrent from the graphene layer 131. One of the electrodes, for example second electrode 122, can be closer to the waveguide 111 to create a potential difference on the graphene layer 131. A silicon waveguide 111 and graphene layer 131 can be electrically isolated by an insulating layer 141, for example, a 10 nm thick layer of silicon dioxide. FIG. 1J displays an optical microscope image of an exemplary photodetector device, in accordance with some embodiments of the disclosed subject matter. The light 151 can transmit through waveguide 111 and be absorbed by graphene layer 131 through evanescent coupling. FIG. 1K displays a scanning electron microscope image of an exemplary photodetector device, in accordance with some embodiments of the disclosed subject matter. As shown in FIG. 1K, the second distance between the second electrode 122 and the waveguide 111 can be about 100 nm. The graphene layer 131 covering on the waveguide 111 can be about 53 μm long.

Referring again to FIG. 1A, the device 100 can include at least one of a voltage source or a current source 161 connected to the first electrode 121. For purpose of illustration and not limitation, a current source 161 can be connected to the first electrode 121. The current source 161 can apply a bias electric field across the graphene layer 131 to enhance the responsivity of the device 100, for example, by enhancing total absorption and total number of generated photocarriers.

In some embodiments, a source of electromagnetic radiation, for example, a light source, can be coupled to the waveguide. The light source can be any source of light 151, for example, monochromatic light or white light. For purpose of illustration and not limitation, the light source can be a laser. For example, the laser can have a wavelength of 1450-1590 nm. The light 151 from the light source can be coupled into the waveguide 111 using at least one coupler coupled to the waveguide 111. The coupler(s) can be any suitable device or mechanism configured to direct light 151 into the waveguide 111. For example, the coupler(s) can include at least one of an optical fiber, a lensed optical fiber, a lens, an edge coupler, a evanescent coupler, a grating coupler, or a butt-coupler.

In some embodiments, a spectral selection mechanism can direct a selected frequency component of electromagnetic radiation to the graphene layer(s) 131. For example, the spectral selection mechanism can include at least one of a superprism, a drop-cavity filter, an echelle gratings, or a scannable interface filter, as described further below.

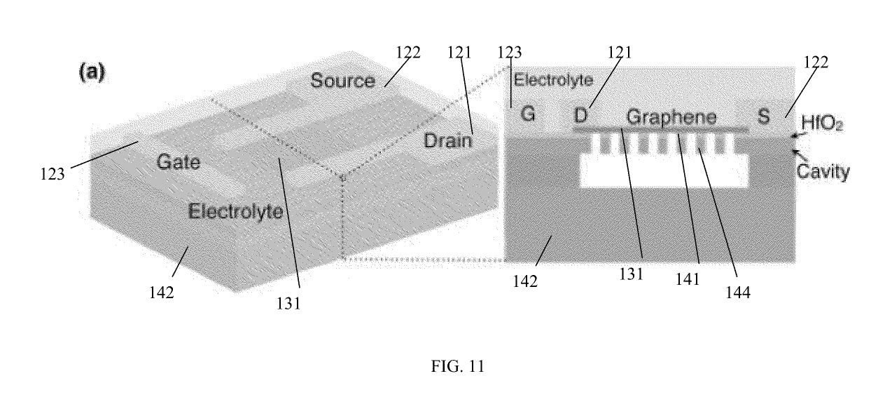

For purpose of illustration and not limitation, and as embodied herein, the device 100 can further include electrical gating to modulate absorption of the at least one graphene layer. For example, FIG. 11 shows a schematic illustration of an exemplary device 1100 for detecting photons including a gate electrode, in accordance with some embodiments of the disclosed subject matter. A third electrode 123 can be disposed proximate to the graphene layer 131. In some embodiments, the third electrode 123 can be positioned so as not to electrically contact the graphene layer 131. The third electrode 123 can be used for electrical gating to change the Fermi energy of electrons in the graphene layer 131, as described below. Voltage can be supplied to the third electrode 123 to apply an electric field across the graphene layer 131. In some embodiments, the third electrode 123 can be embedded in the substrate 142. Additionally or alternatively, at least part of the substrate 142 can be conductive, and the substrate 142 can act as electrical gating. Additionally or alternatively, at least part of the waveguide 111 can be doped to be slightly conductive, and the waveguide 111 can be used for electrical gating. Voltage can be supplied to the doped waveguide 111 to apply an electric field across the graphene layer 131. Additionally or alternatively, a transparent, conductive layer can be disposed above or below the graphene layer 131. The transparent, conductive layer can apply a vertical electric field across the graphene layer 131.

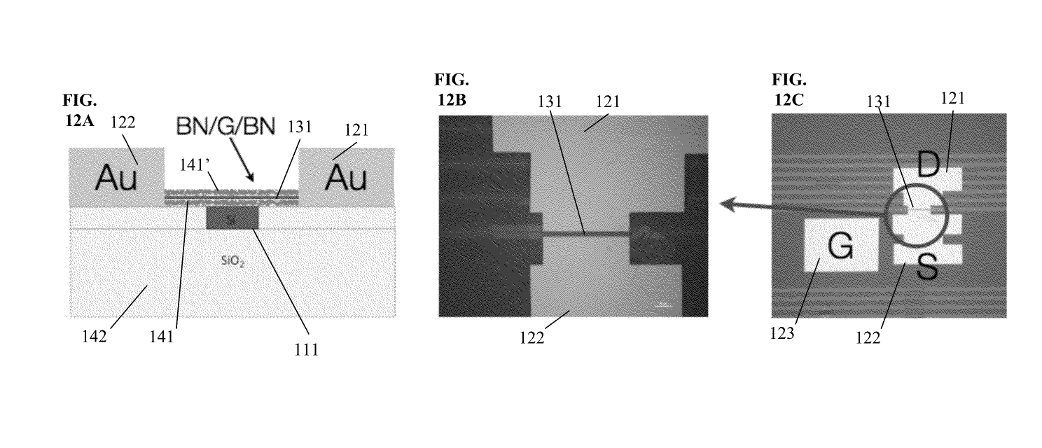

FIG. 12A shows a schematic illustration of an exemplary device 1200 for detecting photons, in accordance with some embodiments of the disclosed subject matter. For purpose of illustration and not limitation, the device can include a substrate 142, a waveguide 111, at least one graphene layer 131, a first electrode 121, and a second electrode 122, as described herein. A first insulating layer 141 can be disposed between the waveguide 111 and the graphene layer 131, as described herein. For example, the insulating layer 141 can be a layer of boron nitride. A second insulating layer 141′ can be disposed on the graphene layer 131 opposite the waveguide 111. The second insulation layer 141′ can be a layer of boron nitride. For example, the second insulation layer 141′ can cap the top surface of the graphene layer 131 to prevent the graphene layer 131 from being influenced by environmental impurities, such as air and moisture. FIG. 12B displays a scanning electron microscope image of an exemplary photodetector device, in accordance with some embodiments of the disclosed subject matter. The first electrode 121 and the second electrode 122 can contact the first and second ends of the graphene layer 131, as described herein. FIG. 12C displays an optical microscope image of an exemplary photodetector device, in accordance with some embodiments of the disclosed subject matter. In addition to the first electrode 121 and the second electrode 122, a third electrode 123 can be disposed proximate to the graphene layer 131. The third electrode 123 can be positioned so as not to electrically contact the graphene layer 131. The third electrode can be used as electrical gating for the graphene layer 131, as described herein.

For purpose of illustration and not limitation, an exemplary device 100 can be characterized under ambient conditions. To confirm the potential difference across the graphene layer(s) 131 near the waveguide 111, a spatial scanning photocurrent image of the device 100 can be obtained with a confocal microscope. The device 100 can be mounted on an X-Y translation stage, for example, with a resolution of 10 nm. A light source, for example, a laser, can illuminate the device 100. For purpose of illustration and not limitation, the laser can have a wavelength of 1450-1590 nm and can be focused to have a spot size of about 0.5-2 μm in diameter. For example, the laser having a wavelength of 1,550 nm can illuminate the device from a normal incidence angle, and the laser can be focused into a spot with dimension of 0.9 μm. The photocurrent of the graphene layer 131 can be measured, for example, with zero drain-source voltage, and the confocal reflectivity can be monitored simultaneously, for example, with a photodiode to locate the electrodes. The laser can be modulated at a low frequency, for example, a frequency from 0.1 to 10 kHz such as 2 kHz, and a lock-in amplifier can be used to detect the resulting modulation of the photocurrent. For example, the lock-in amplifier can be connected to the first electrode 121 and the second electrode 122. For purpose of illustration and not limitation, the lock-in amplifier can be a commercially available lock-in amplifier such as a Stanford Research Systems SR830.

For purpose of illustration and not limitation, photocurrent measurements from the exemplary device 100 can be performed under ambient conditions. A scanning photocurrent image of the device can be measured on a vertical confocal microscope setup with a normal incidence. A laser at the wavelength of 1550 nm can be focused by an objective lens with numerical aperture of 0.9 into a spot with dimension of 0.9 μm. The device 100 can be scanned with a step of 100 nm on a x-y piezo-actuated transition stage. The photocurrents at each point can be constructed into a scanning image on a computer. The transmission loss of the waveguide 111 and the responsivity of the device 100 in the waveguide-integrated configuration can be tested on an edge-coupling setup. A polarization controller can be used to change the polarization to match with the TE guided mode of the waveguide 111. A lensed fiber at each side of the chip can focus incident light into a small spot, enabling efficient coupling into and out of the waveguide 111 with SU8 couplers. In both the ambient and waveguide-integrated cases, the incident laser can be modulated internally, for example, at a frequency of 2 kHz, and the short-circuit photocurrent signal can be detected with a current pre-amplifier and a lock-in amplifier. For example, the incident laser can be a HP telecom laser with tunable range of 1450 nm to 1590 nm.

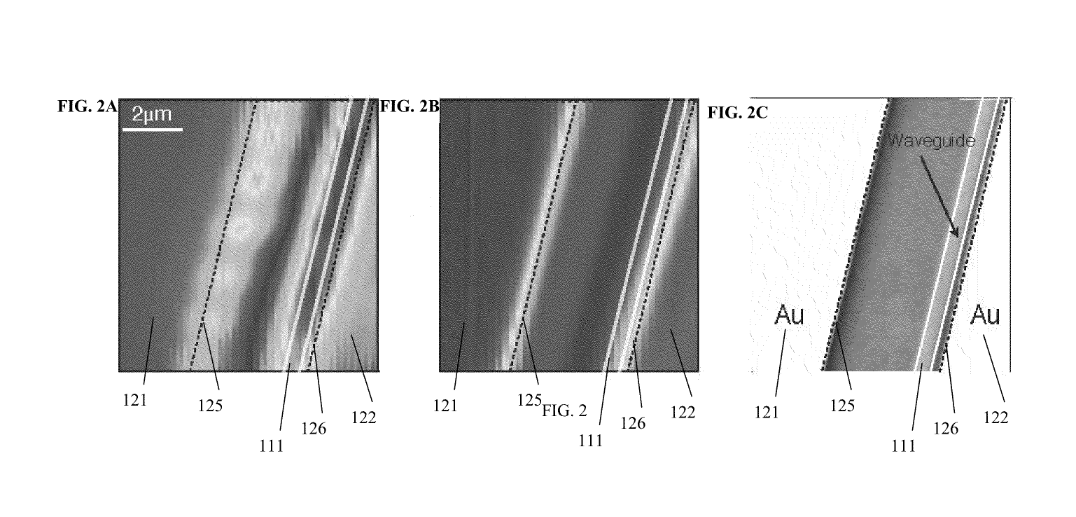

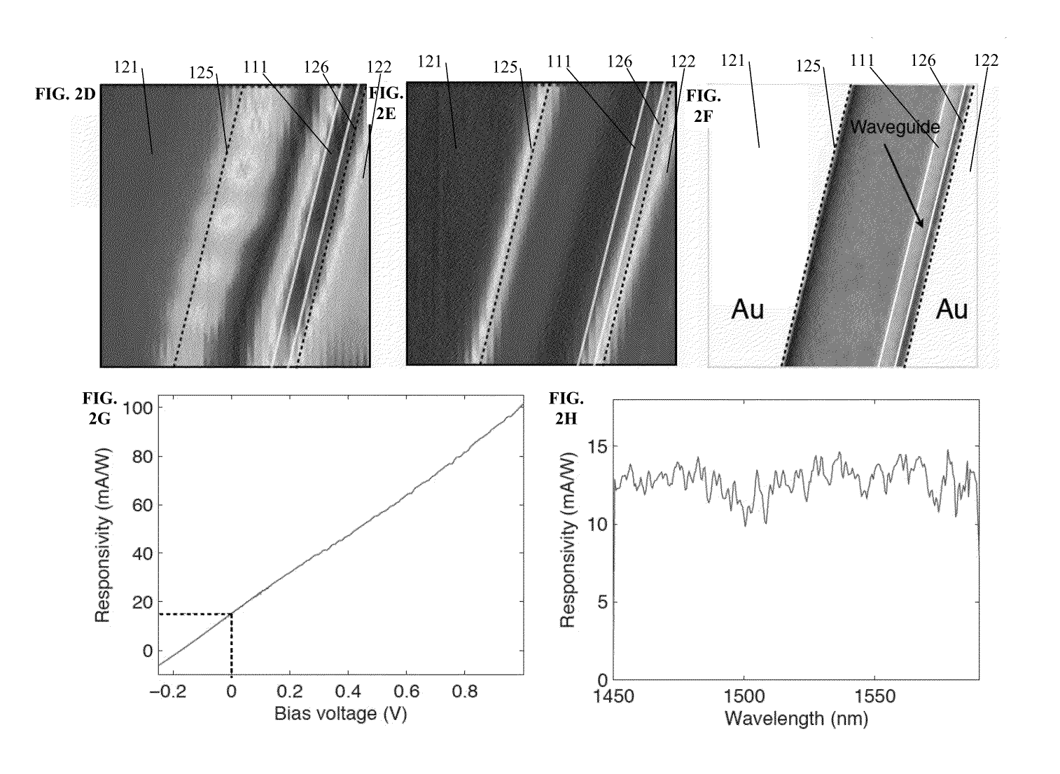

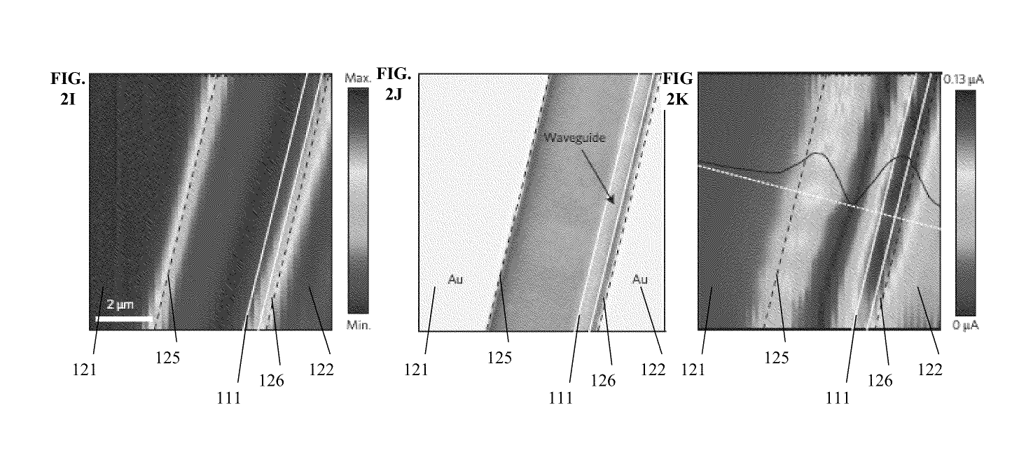

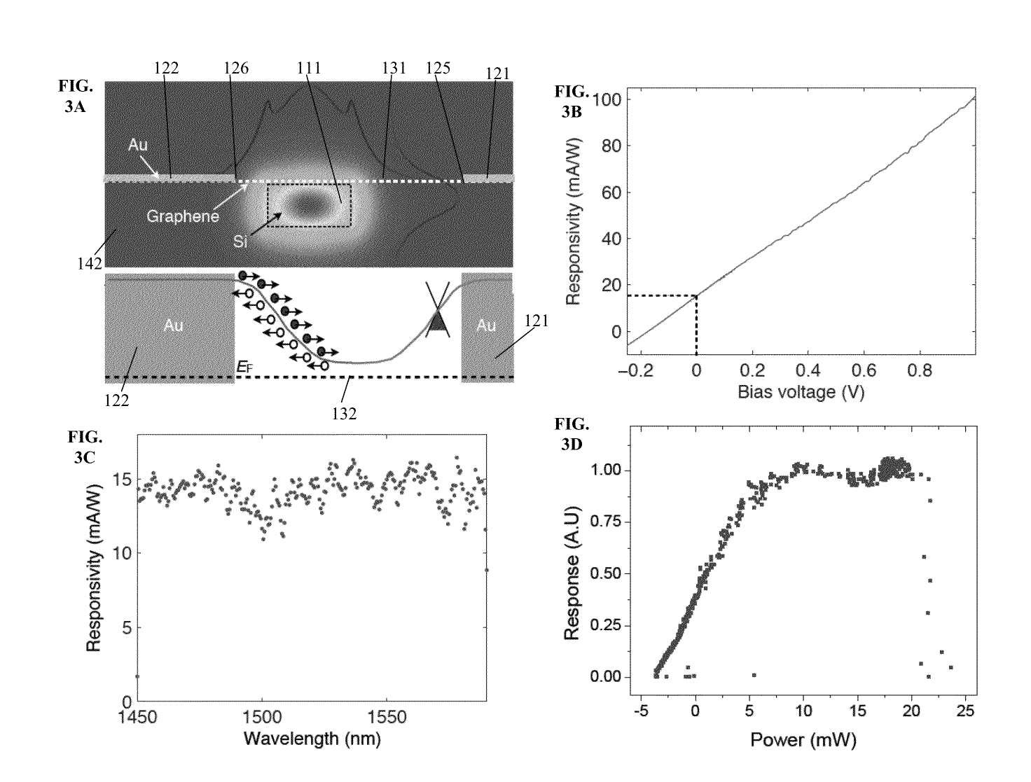

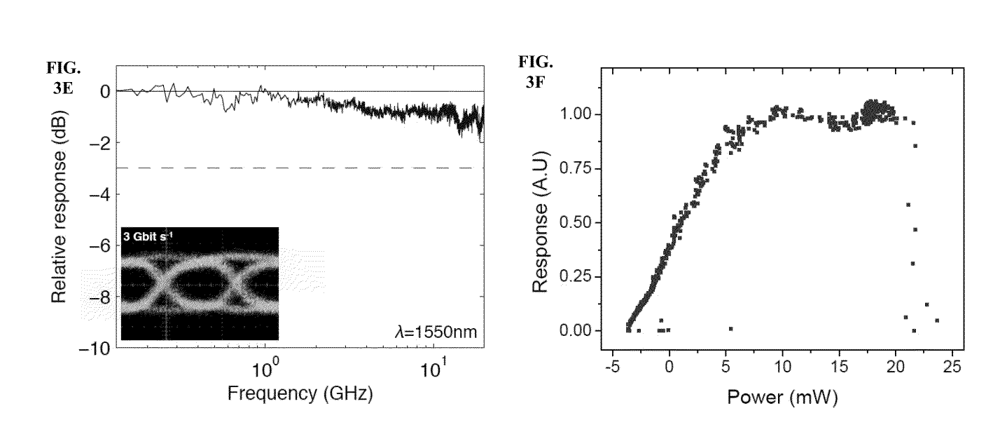

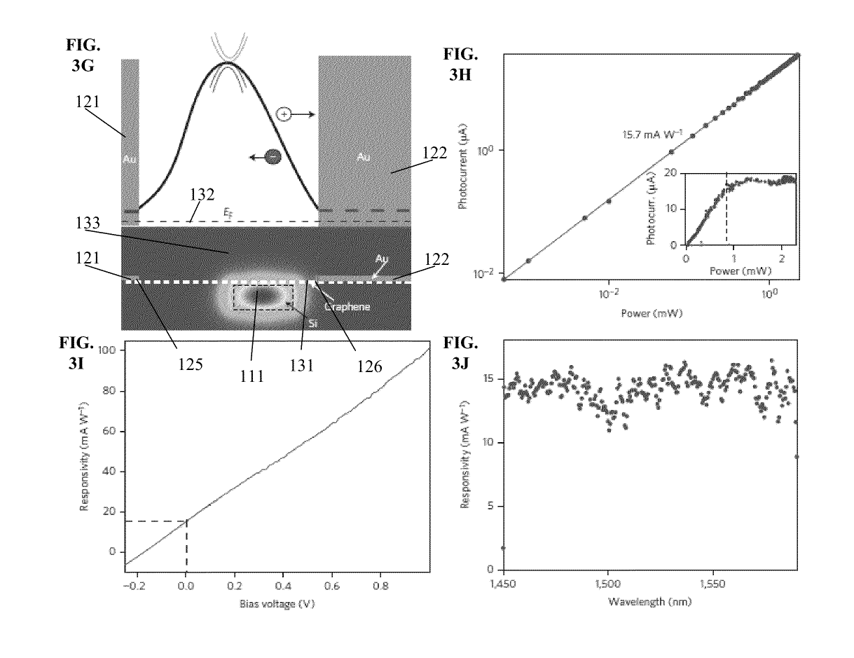

FIG. 2A shows a scanning photocurrent image of an exemplary device 100 measured on a vertical confocal microscope setup with a normal incidence, in accordance with some embodiments of the disclosed subject matter. For purpose of illustration and not limitation, a laser can be chosen with a wavelength of 1550 nm with the incident power of 1.5 mW. The measurement can be implemented at zero source-drain voltage and show a peak photocurrent of 0.13 μA. FIG. 2B shows the corresponding scanning optical reflection image of the exemplary device 100, in accordance with some embodiments of the disclosed subject matter. First electrodes 121 and second electrode 122 can be seen by their effective reflections, as shown by the dashed black lines. FIG. 2C shows an SEM image of the corresponding measured section of the exemplary device 100, indicating the positions of the waveguide 111, first metal electrode 121, and second metal electrode 122, in accordance with some embodiments of the disclosed subject matter. The fit of the first electrode 121 and second electrode 122 can be shown by dashed black lines, and the location of the silicon waveguide 111 can be obtained, as indicated by the white solid lines in FIGS. 2A-C. FIGS. 2A-C can have the same dimension scale and the scanning photocurrent image can indicate a narrow potential difference at the two metal/graphene junctions 125, 126, and the second metal-doped junction 126 can overlap with the waveguide. The width of the metal-doped junction 125, 126 can be 200-500 nm, depending on the doping level due to the substrate. The junction width can be broad, for example, about 0.9 μm, which can be due to the diffraction limit of the incident light. For example, the diffraction limit can be the limit to which the volume of light in an optical waveguide can be decreased. The diffraction limit can be less than the size of the metal-doped junction 125, 126, for example, so the photocurrent generation efficiency can be enhanced. Additionally or alternatively, one of the junctions, for example, the second metal doped junction 126, can overlap with the waveguide effectively, as depicted in FIG. 2A. A peak photocurrent generated on the device can be, for example, about 0.13 μA with an excitation power of, for example, 1.5 mW, measured after the objective lens, and this photocurrent can indicate a low photodetection efficiency of the device as a normal incidence photodetector.

FIGS. 2D-F show photocurrent measurements of an exemplary device 101. FIG. 2D shows a spatial resolved photocurrent image of an exemplary device 101 obtained at zero source-drain voltage and a laser power of 1.5 mW, in accordance with some embodiments of the disclosed subject matter. FIG. 2E shows a corresponding optical reflection image measured on a vertical confocal microscope setup with a normal incidence of the exemplary device 101, in accordance with some embodiments of the disclosed subject matter. The black dashed lines can show the edge of the first metal electrode 121 and the second metal electrode 122, and the white solid lines can indicate the waveguide 111. FIG. 2F shows an SEM image of the corresponding measured section of the exemplary device 101, indicating the positions of the waveguide 111 and first and second metal electrodes 121, 122, in accordance with some embodiments of the disclosed subject matter. FIG. 2G shows a plot of the bias dependence of the photodetection on graphene later 131 excited by light coupled from the waveguide 111 through its evanescent field, in accordance with some embodiments of the disclosed subject matter. The plot shows a responsivity of 15.7 mA/W. FIG. 2H shows the a plot of photoresponsivity of the exemplary device 101 with light transmitting in the waveguide 111 respective to the excitation wavelength, in accordance with some embodiments of the disclosed subject matter. This plot shows a broadband flat responsivity of the device 101.

FIG. 2I shows a scanning reflection image of an exemplary device 102, indicating the edges of the metal electrodes, in accordance with some embodiments of the disclosed subject matter. FIG. 2J shows an SEM image of the measured section of the exemplary device 102, in accordance with some embodiments of the disclosed subject matter. The waveguide can be located by correlating the reflection image in FIG. 2I and the SEM image in FIG. 2J. FIG. 2K shows a spatially resolved photocurrent (amplitude) image of the exemplary device 102 measured at zero bias voltage and representing two photocurrent strips around the metal/graphene junctions, in accordance with some embodiments of the disclosed subject matter. A photocurrent profile plotted along the dashed white line is superposed on the image. The scale bar can apply to all panels. Dashed black lines show the edges of the first electrode 121 and second electrode 122, and solid white lines show the edges of the waveguide 111. The scanning photocurrent image can indicate narrow metal-doped junctions 125, 126 at the metal/graphene interfaces, one of which, for example, junction 126, can overlaps with the waveguide

Spatially resolved photocurrent measurements can be used to confirm the integrity of the metal-doped graphene junctions 125, 126. For purpose of illustration and not limitation, the device 102 can be mounted under a confocal microscope on an x-y translation stage and illuminated from above with a 1,550 nm continuous-wave (c.w.) laser. Referring to FIG. 2I, a scanning reflectivity image of the device can show the overall device structure, with the metal electrodes 121, 122 exhibiting higher reflectivity than the silicon waveguide 111 and SiO₂ substrate 142. Referring to FIG. 2K, by correlating the metal electrode 121, 122 edges in the reflection image to those in the corresponding SEM image of the measured section, the location of the silicon waveguide 111 can be obtained. FIG. 2K shows a map of the photocurrent obtained under zero bias voltage. The two narrow regions of high photocurrent along the metal/graphene junctions 125, 126 can indicate the expected built-in electric field between the metal-doped junctions 125, 126 and the bulk graphene layer 131. The metal-doped junctions 125, 126 exist at the metal/graphene interface and extend into the graphene layer 131 channel between the two electrodes 121, 122. Because of the approximately micrometer-scale spot size of the excitation laser, photocurrent under the metal electrodes 121, 122 can be observed. A region of high photocurrent can coincide with the waveguide 111 and reached 13 nA, which can correspond to an excitation power of 50 μW measured after the objective lens. This responsivity of 2.6×10⁻⁴ A W⁻¹ can correspond to the low photodetection efficiency of a graphene photodetector as expected for normal-incidence excitation.

FIG. 3A shows an image of a simulated exemplary device 100, in accordance with some embodiments of the disclosed subject matter. As a waveguide 111 integrated photodetector, the metal-doped junctions 125, 126 on graphene layer 131 can efficiently separate the photocarriers excited by the evanescent field of the waveguide 111. For purpose of illustration and not limitation, the top of FIG. 3A displays a simulated electrical field of the transversal electric (TE) mode of the silicon waveguide 111 coupled with the graphene bi-layer 131 (white dashed line) and the metal electrodes 121, 122. The field distributions along the graphene bi-layer 131 and along the middle vertical line of the exemplary device 100 are shown superposed on the image as the top and left curves, respectively, and these distributions can present a strong coupling between graphene bi-layer 131 and the guided mode. For example, using the effective index of the simulated guided mode, the graphene layer absorption coefficient can be calculated to be 0.085 dB/μm. The closer metal electrode 122 can couple with the guided light, as indicated in the top superposition line, and the absorption coefficient can be, for example, about 0.007 dB/μm. The graphene bi-layer 131 can dominate the absorption of the guided light, for example, with a factor more than 92%, which can ensure an efficient external quantum efficiency. The absorption of the metal electrode 122 can be reduced by reducing the metal thickness at the section coupling with the waveguide 111. The bottom of FIG. 3A shows the potential profile in the exemplary device 100 with zero drain-source bias. The effective overlap between the optical field and the potential difference around the metal/graphene junctions 125, 126 can be observed. The graphene band profile can show band bending at the metal/graphene junctions 125, 126. The inherent electric field on the graphene layer 131 can present an overlap, for example, an overlap of about 250 nm, with the optical field distribution on graphene layer 131, an overlap which can enable efficient separation of the photocarriers.

For purpose of illustration and not limitation, the simulations of the guided mode in the waveguide 111 coupled with graphene bi-layer 131 and metal electrodes 121, 122 can be carried out using a finite element method (COMSOL). In an exemplary simulation, a 1.4 nm thick graphene bi-layer 131 and 40 nm thick metal (Au) electrodes 121, 122 can be located on the planarized platform with 10 nm SiO₂ insulating layer 141 between the graphene bi-layer 131 and the silicon waveguide 111. The second metal electrode 122 can be 100 nm from the waveguide 111 transversally. The refractive index of SiO₂, silicon, Au, and graphene can be simulated as 1.48, 3.4, 0.55+1.15i, and 2.38+1.68i, respectively.

The performance of the exemplary device 100 acting as a waveguide-integrated photodetector can be tested by exciting the device 100 with light transmitting in the waveguide 111. Light can be coupled in and out of the waveguide 111 with at least one couple, as described herein. For example, lensed optical fibers and SU8 butt-couplers can be coupled to both ends of the silicon waveguide 111. The polarization of the input light can be controlled to match the TE mode of the waveguide 111. The graphene absorption can be determined by measuring the transmission of the waveguide 111 before and after the transfer to the graphene bi-layer 131. For example, a 4.8 dB transmission loss can be caused by a 53 μm long graphene bi-layer 131, which can be higher than the 0.1 dB absorption in the normal incidence configuration. The transmission loss can indicate an absorption coefficient of 0.9 dB/μm, which can agree with simulation results. More efficient graphene absorption of the photodetector device 100 can be achieved by extending the length of graphene bi-layer 131 and coupling the graphene bi-layer 131 with a transversal magnetic (TM) mode to enable stronger field on the top of the waveguide 111. The wavelength of the excitation laser can be scanned from 1450 nm to 1590 nm, and the attenuation due to graphene can be uniform over this spectral range.

To measure the photodetection efficiency of the exemplary device 100, the input laser can be modulated with a low frequency, and the photocurrent can be detected through a pre-amplifier and a lock-in amplifier. For purpose of illustration and not limitation, the wavelength of the input laser can be set at 1550 nm. After considering the losses due to the end-coupling and waveguide 111 scattering, the power incident into the waveguide-graphene section can be Pᵢₙₚᵤₜ=35 μW. With zero source-drain bias (V_{B}), a photocurrent can be measured to be Iₚₕₒₜₒ=0.55 μA.

FIG. 3B shows a plot of the responsivity versus source-drain bias voltage of the exemplary device 100, in accordance with some embodiments of the disclosed subject matter. The device 100 can be excited by the evanescent field of light in the waveguide 111. For purpose of illustration and not limitation, the incident laser can have a wavelength of 1550 nm. The photocurrent can indicate an external responsivity of the photodetection (Iₚₕₒₜₒ/Pᵢₙₚᵤₜ) as 15.7 mA/W at V_{B}=0, a responsivity which can be an order of magnitude higher than certain graphene-based photodetectors. This photodetection efficiency can be due at least in part to the longer interaction length between light from waveguide 111 and the graphene bi-layer 131 and to the efficient separation of the photon excited electron-hole pairs with the aid of the local electric field in graphene bi-layer 131. The internal quantum efficiency due to the potential difference on graphene can be estimated to be as high as 4% at zero source-drain bias. By electrically gating the graphene layer, the depth and position of the potential difference can be tuned, which can allow even higher internal quantum efficiency.

FIG. 3C shows a plot of the photoresponsivity of the exemplary device 100 as a function of the excited wavelength from 1450 nm to 1590 nm, in accordance with some embodiments of the disclosed subject matter. The plot can show a broadband flat responsivity of the device across the spectral range. For purpose of illustration and not limitation, the responsivity of the photodetector at zero bias can be measured by scanning the laser wavelength across the spectral range. The responsivity spectrum of the device over the spectral range from 1540 nm to 1590 nm can be flat.

Photoresponse measurements can be performed at the wavelength of 2.0 μm using a pulsed optical parametric oscillator (OPO) source. For example, an OPO laser pumped by a Ti:Sap laser with duration time of 220 fs and repetition rate of 78 MHz can be used. The wavelength of the OPO laser can be at 2.0 μM with a linewidth of about 20 nm. FIG. 3D shows a plot of photocurrent of the exemplary device 100 as a function of the incident power from a pulsed laser, in accordance with some embodiments of the disclosed subject matter. The plot can show saturation starts at the power of about 9.6 mW. For purpose of illustration and not limitation, the incident power in the horizontal axis can be the power transmitted to the device 100. Due to coupling loss between the silicon waveguide 111 and the guided light in fiber 152, the power delivered to the graphene photodetector can be less, for example, about 760 μW. The saturation of the photocurrent can be observed to start at the received incident power of 760 μW. This saturation can be attributed at least in part to the Pauli blocking on the graphene layer(s) 131 under a high power, ultrafast pulsed laser, for example, a pulsed laser with a temporal width from 1 fs to 1 ns. The exemplary device 100 can have a high saturation threshold.

FIG. 3E shows a plot of dynamic opto-electrical response of an exemplary device 101. The relative AC response of the device as a function of frequency can show about 1 dB degradation of the signal. The inset displays a about 3 Gbit s⁻¹ optical data link test of the exemplary device 101. The inset shows a complete open eye diagram. FIG. 3F shows a plot of responsivity of the exemplary device 101 as a function of the incident power. Photocurrent saturation can start at an incident power of about 5 mW.

FIG. 3G shows, at the top, a simulated potential profile (black solid line) across the graphene channel of an exemplary device 102. The diagram shows band bending around the two metal electrodes 121, 122. The dashed line 132 denotes the Fermi level, E_{F}. At the bottom, FIG. 3G shows a simulated electric field of the TE waveguide 111 mode. The field intensity at the graphene position is shown dashed line 131. The top and bottom images in FIG. 3G are aligned horizontally by referring to the relative position of the waveguide 111; the position of the second electrode 122 can be symbolic. The simulation of the guided mode can be carried out using a finite element method (COMSOL). For purpose of illustration and not limitation, the structure of the exemplary device 102 used in the simulation is shown in FIG. 3G. The thicknesses of the graphene bilayer 131 and gold electrode 121, 122 can be simulated to be 1.4 nm and 40 nm, respectively. The refractive indices of SiO₂, silicon, gold and graphene can be simulated as 1.48, 3.4, 0.55+11.5i and 2.38+1.68i, respectively, for light in the telecommunications wavelength range of wavelength 1,550 nm.

For purpose of illustration and not limitation, to test the performance of the exemplary waveguide-integrated graphene detector device 102, light can be coupled into and out of the waveguide 111 using lensed fibers and SU8 edge couplers at each end of the silicon waveguide 111. The polarization of the input light can be controlled to match the TE mode of the waveguide 111. Using transmission measurements from waveguide 111 before and after the evanescent field transfer to the graphene bilayer 131, a transmission loss of can be estimated to be 4.8 dB, which can be due at least in part to the 53-μm-long graphene bilayer 131, which can be greater than the 0.1 dB absorption in the normal-incidence configuration. The transmission loss can indicate an absorption coefficient of 0.09 dB μm⁻¹. Estimating the absorption from the complex effective index of the simulated guided mode, the absorption coefficient for the graphene bilayer 131 can be estimated to be slightly lower, for example, 0.085 dB μm⁻¹. The greater absorption coefficient obtained in the exemplary device 102 can be attributed at least in part to the extra scattering and back-reflection caused by the graphene/waveguide interface. The contribution of the 40-nm-thick metal contact to the total waveguide absorption can be calculated and can indicates an absorption coefficient of about 0.009 dB μm⁻¹. Accordingly, the graphene layer can be responsible for about 90% of the absorption of the light from the waveguide 111.

For purpose of illustration and not limitation, photocurrent measurements for an exemplary device 102 can be performed under ambient conditions. A scanning photocurrent image can be measured on a vertical confocal microscope set-up using 1550 nm laser radiation focused at normal incidence to a spot size of 900 nm. Photocurrent images can be collected by scanning an x-y piezo-actuated stage in 100 nm steps. The graphene absorption and photoresponsivity of the device 102 in the waveguide-integrated configuration can be measured on an edge-coupling set-up using lensed fibers. A fiber-based polarization controller can be used to match the input polarization with the TE guided mode. In both the ambient and waveguide-integrated measurements, the incident laser can be modulated internally at a frequency of 1 kHz, and the short-circuit photocurrent signal can be detected with a current preamplifier and a lock-in amplifier. The excitation laser can be, for example, an HP 8168F with a tuning range of 1450-1590 nm. For measurements of the detector responsivity under pulsed excitation, an OPO laser operating at a wavelength of 2000 nm and providing 250 fs pulses at a repetition rate of 78 MHz can be used.

To measure the photodetection efficiency of the exemplary device 102, a 1550 nm continuous wave input laser can be modulated at a low frequency, and the photocurrent through a preamplifier and a lock-in amplifier can be detected. FIG. 3H shows a plot of the detected photocurrent (Iₚₕₒₜₒ) as a function of incident power (Pᵢₙₚᵤₜ) obtained at zero bias voltage (V_{B}=0). Here, Pᵢₙₚᵤₜ can be the power reaching the waveguide-integrated graphene detector device 102 and can be estimated by considering the input facet coupling loss and the silicon waveguide 111 transmission loss. This measurement can indicate an external responsivity (Iₚₕₒₜₒ/Pᵢₙₚᵤₜ) of 15.7 mA W⁻¹, which can be a magnitude higher than that obtained for normal incidence. This responsivity improvement can be attributed at least in part to the longer light-graphene interaction length and the efficient separation of the photo-excited electron-hole pairs resulting from the local electric field across the metal-doped junction 126. Moreover, the plot shows that the photocurrent can approach zero linearly under low-power optical excitation, which can indicate vanishing dark current under zero-bias operation. The inset shows photocurrent as a function of excited power from a pulsed OPO laser at a wavelength of 2000 nm.

The photocurrent profile plotted in FIG. 2K can be devolved with the spot size of the excitation laser and can be numerically integrated along the dashed white line to obtain a relative potential profile across the graphene channel, as shown in the top part of FIG. 3H. The potential profile can show that the graphene layers 131 can have potential gradients around the boundaries of the gold electrodes 121, 122, and the potential gradients can yield the corresponding internal electric field. The graphene beneath the two metal electrodes 121, 122 can have the same p-type doping level, which can be lower than the intrinsic doping of the graphene channel. Band bending with opposing gradients can occur at the two metal-doped junctions 125, 126. The bottom panel of FIG. 3H presents the simulated transverse electric (TE) mode of the silicon waveguide 111, which can be coupled to the graphene bilayer 131 (dashed white line) and the two metal electrodes 121, 122. The field distribution 133 along the graphene layers 131 can be plotted and can correspond to the photocarrier density. The top and bottom images can be aligned horizontally according to the position of the waveguide 111. A potential gradient can overlap with the waveguide mode. Additionally or alternatively, the absence of an overlap between the optical field and the potential difference created by the first electrode 121 (as shown in FIG. 3H) can ensure the acceleration of electrons (or holes) in one direction and the absence of cancelation in the net photocurrent. Therefore, an asymmetric metal electrode design can provide a high internal quantum efficiency for collecting photocarriers.

FIG. 3I shows the responsivity as a function of bias voltage of the exemplary device 102. The external responsivity of the photodetector device 102 can be further enhanced by applying a source-drain voltage across the photocarrier generation region. When V_{B}=0, the external bias can build an extra electric field along the direction of the internal built-in field and therefore can enhance the separation of photocarriers, which can increases the responsivity and can enable a value high as 0.108 A/W at V_{B}=1 V. If V_{B}=0, the photocurrent can decrease due to the compensation between the external and internal fields and can achieve zero at V_{B}=175 mV. The photocurrent can change its sign if the bias is decreased further. This bias dependence can demonstrate the photocurrent can arise from the electric field. The responsivity can be linear with respect to the bias voltage, without a saturation even under a high bias, and this responsivity can indicate that the wide evanescent field of the waveguide can excite many photocarriers on the graphene layer 131 and can enables higher photocurrent of the device.

FIG. 3J shows the broadband, uniform responsivity of the exemplary device 102 over a wavelength range from 1450 nm to 1590 nm at zero bias. The external responsivity can be further enhanced by applying a bias voltage V_{B} across the photocarrier generation region. The responsivity can be plotted after subtracting the dark current. When V_{B}>0, the external bias can induces an additional electric field along the direction of the built-in field and can enhance the separation of photocarriers, increasing the responsivity to a value as high as 0.108 A W⁻¹ at V_{B}=1 V. If V_{B}<0, the photocurrent can decrease due to compensation between the external and internal fields and can vanish for V_{B}=−175 mV. The photocurrent can change sign when the bias is decreased further. The responsivity can be linear with respect to the bias voltage, without saturation even under a high bias, which can indicate that the evanescent field of the waveguide 111 can excite a large charge carrier density in the graphene layer 131. Thus, a higher photocurrent can be expected under increased bias voltage. To suppress the enhanced dark current for high bias voltages, a bandgap can be induced in the graphene bilayer 131 by the application of a perpendicular electric field.

A uniform photoresponse can be expected across a wide range of wavelengths due at least in part to the spectrally flat absorption of graphene. Experimentally, a nearly flat photocurrent can be observed in spectrally resolved photodetection measurements under zero bias voltage from 1450 nm to 1590 nm for a fixed optical input power, as shown in FIG. 3J. The flat response can suggest carrier multiplication. The absorption length of the graphene sheet can enable operation at high power, at least in part because saturation towards the front of the graphene layer 131 can be compensated by additional absorption further along the waveguide 111. Experimentally, a lack of saturation of photocurrent can be observed under continuous wave laser excitation for launching powers up to 10 dBm into the detector device 102. For purpose of illustration and not limitation, photoresponse measurements can be performed using a pulsed optical parametric oscillator (OPO) source at a wavelength of 2000 nm. For example, the pulse duration can be 250 fs. The inset of FIG. 3H can show the photocurrent as a function of the average incident power of the OPO pulsed source and can indicate a saturation of the photocurrent for an incident power near 760 μW. For example, under these conditions, the graphene layer can experience a peak intensity of 6.1 GW cm⁻², similar to the threshold of saturable absorption in graphene due to Pauli blocking.

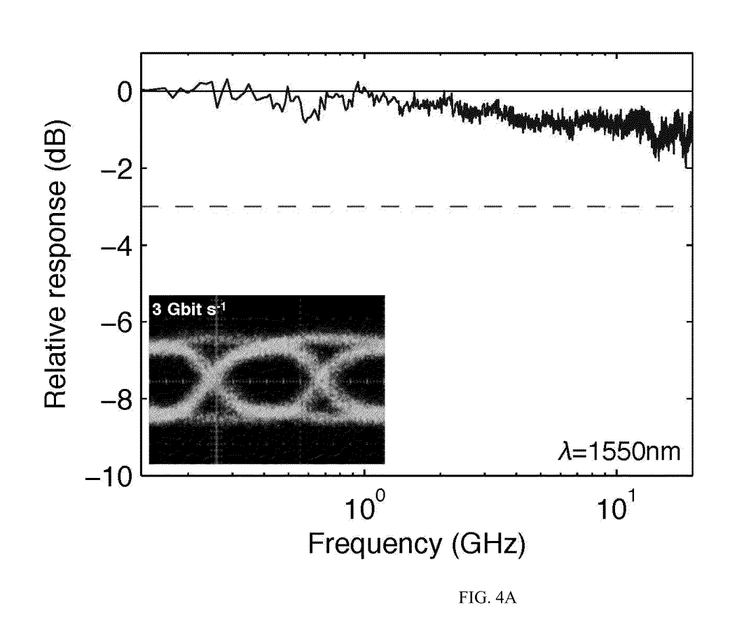

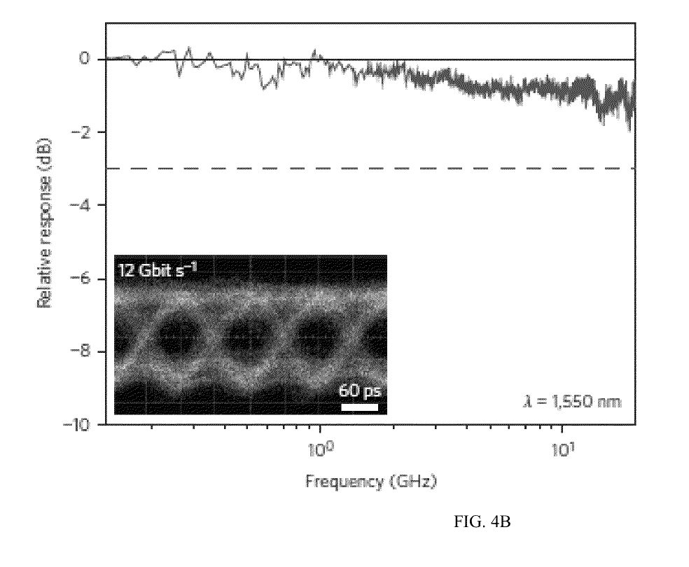

For purpose of illustration and not limitation, the dynamic opto-electrical response of the device can be examined using a commercial lightwave component analyzer (LCA) in combination with a network analyzer (NA), which can have a frequency range from 0.13 GHz to 20 GHz. A modulated optical signal at a wavelength of 1550 nm with an average power of 1 mW emitted from the LCA can be coupled into the device and the electrical output can be measured, for example, as the S₂₁ parameter of the NA. FIG. 4A shows a plot of the AC photoresponse of an exemplary device 100 with zero bias voltage as a function of frequency. The plot can show about 1 dB degradation of the signal at the frequency of 20 GHz. The high carrier mobility of graphene can enable an intrinsic response of the photodetection faster than 260 GHz. The observed degradation of the high speed response can be attributed at least in part to the large capacitance from the relatively large metal electrodes 121, 122 and graphene sheet 131. Another factor that can account at least in part for the degradation can be the un-calibrated microwave probe having a limited response at the high frequency. The inset displays a 3 Gbit s⁻¹ optical data link test of the exemplary device 100, showing a complete open eye diagram.

For purpose of illustration and not limitation, frequency response characterization can be achieved using an Agilent Lightwave Component Analyzer. The optical fiber output of the LCA (0 dBm) can be focused by a lensed fiber into an SU8 coupler coupled to an end of the waveguide 111. The photocurrent signal can be extracted, for example, through a microwave probe from GGB Industries and fed into a parameter network analyzer, such as an Agilent E8364C. The frequency response (e.g., scattering parameter S₂₁) can be recorded as the modulation frequency can be swept between 130 MHz and 20 GHz. For the eye-diagram measurements at a data rate of 3 Gbit s⁻¹, a pulsed pattern generator with an internal pseudo-random bit sequence generator can be used to modulate the light from a 1550 nm laser, for example, with a JDS Uniphase MachZehnder modulator. The optical signal can be amplified with the EDFA and fed into the detector device 100. A radio-frequency power amplifier with a gain of 15 dB and bandwidth of 6 GHz can be used to amplify the detector device 100 output and the eye-diagram can be measured with an Agilent 86100A wide-band oscilloscope.

For purpose of illustration and not limitation, the device 100 can be used in a 3 Gbit s⁻¹ optical data link. We use a pulsed pattern generator with a maximum 3 Gbit s⁻¹ internal electrical bit stream from a pseudo-random bit sequence (PRBS) generator with (2⁷−1) pattern length to modulate the laser with a wavelength of 1550 nm. The generated optical bit stream can be amplified to an output power of 20 dBm using an erbium-doped fiber amplifier and coupled into the waveguide-integrated graphene detector device 100, as described herein. The output electrical data stream from the graphene detector can be amplified and fed to an oscilloscope to obtain an eye diagram. As shown in the inset of FIG. 4A, a completely open eye diagram can be obtained at 3 Gbit s⁻¹, indicating that graphene can be used for optical data transmission.

FIG. 4B shows a plot of dynamic relative AC opto-electrical photoresponse of an exemplary device 102 as a function of light intensity modulation frequency. The plot can show about 1 dB degradation of the signal at a frequency of 20 GHz. Unlike certain semiconductors, both electrons and holes in graphene can have high mobility, and a moderate internal electric field can allow ultrafast and efficient photocarrier separation. For purpose of illustration and not limitation, the high-speed response of the device 102 can be examined using a commercial lightwave component analyzer (LCA) with an internal laser source and network analyzer (NA) over a frequency range from 0.13 GHz to 20 GHz. A modulated optical signal at a wavelength of 1550 nm with an average power of 1 mW emitted from the LCA can be coupled into the device, and the electrical output can be measured through a radiofrequency microwave probe. The frequency response of the device 102 can be analyzed, for example, as the S₂₁ parameter of the network analyzer. FIG. 4B can display the AC photoresponse of the device at zero bias, showing about 1 dB degradation of the signal at 20 GHz. The high carrier mobility of graphene can be estimated to result in an intrinsic photoresponse faster than 640 GHz. The limited dynamic response can be attributed at least in part to a large capacitance from the relatively large device area.

The inset of FIG. 4B displays a 12 Gbit s⁻¹ optical data link test of the exemplary device 102, showing a clear eye opening. For purpose of illustration and not limitation, a pulsed pattern generator with a maximum 12 Gbit s⁻¹ internal electrical bit stream can modulate a 1550 nm continuous wave laser via an electro-optic modulator. About 10 dBm average optical power can be launched into the waveguide graphene detector. The output electrical data stream from the graphene detector can be amplified and sent to a digital communication analyzer to obtain an eye diagram. As shown in the inset, a clear eye opening diagram can be obtained at 12 Gbit s⁻¹. The device 102 can operate with a data link at speeds higher than 12 Gbit s⁻¹.

For purpose of illustration and not limitation, the dynamic response rate of the graphene photodetector can be characterized using a commercial LCA (Agilent 8703) with an internally modulated laser source and a network analyzer. The output of the LCA (e.g. at a wavelength of 1550 nm) can be coupled into the photodetector device 102. The photocurrent signal can be extracted through a G-S microwave probe (e.g. from Cascade Microtech) with frequency capability up to 40 GHz and can be fed back to the input port of the network analyzer. The frequency response (scattering parameter S₂₁) can be recorded as the optical modulation frequency can be swept between 0.13 GHz and 20 GHz. For eye-diagram measurements at a data rate of 12 Gbit^{s-1}, a pulse pattern generator (e.g. from Anritsu MP1763B) with an internal pseudo-random bit sequence (e.g. with a length of 2¹¹−1) can be used to drive a JDS Uniphase Mach-Zehnder modulator to modulate a 1550 nm continuous wave laser. The optical signal can be amplified with an erbium-doped fiber amplifier and coupled into the photodetector. The electrical output of the detector can be passed through a radiofrequency power amplifier (e.g. a ZVA−183w+) with a gain of 30 dB and bandwidth of 18 GHz, and the eye diagram can be recorded, for example, using an Agilent DSO81004A wide-band oscilloscope.

As described herein, the extended interaction between the graphene layer(s) 131 and the evanescent light from the waveguide 111 can enable a notable responsivity of photodetection, which can be close to the responsivity of certain commercial photodetectors. Owing to the high carrier mobility of graphene, a waveguide-integrated graphene photodetector, such as device 100, device 101, and/or device 102, can display a high frequency response and can enable a valid optical application for a high speed optical data link. These devices can work at zero bias, for example, allowing low-power consumption on-chip. A waveguide-integrated graphene photodetector can combine advantages of compact size, zero-bias operation, and ultrafast response over a broad range of wavelengths and can enable novel architectures for on-chip optical communications.

For purpose of illustration and not limitation, by designing a potential difference of graphene coupled with the evanescent field of a waveguide mode, a responsivity of the photodetection can be higher than 0.1 A/W. This photodetection can represent an improvement of two orders of magnitude over certain graphene-based photodetectors. For example, and as embodied herein, such a photodetector device can have a dynamic response that does not degrade for optical intensity modulations up to 20 GHz under the zero-bias condition and can show a clear open eye diagram for an optical link of at least 3 Gbit s⁻¹. The fabrication of such a waveguide-integrated graphene photodetector can be full CMOS-compatible, as described below, and can be more straightforward than the integration of germanium photodetectors.

For purpose of illustration and not limitation, the metal-doped junction(s) 125, 126 on the graphene layer(s) 131 across the waveguide 111 can allow ultrafast operation at zero-bias, providing low power consumption, as described herein. Broadband spectral photodetection can be confirmed from 1450 nm to 1590 nm with a flat responsivity, as described herein.

For purpose of illustration and not limitation, a high-performance waveguide-integrated graphene photodetector can include extended interaction length between the graphene layer 131 and the waveguide 111 optical mode, which can result in a notable photodetection responsivity of 0.108 A W⁻¹, which can approach that of certain non-avalanche photodetectors. This responsivity can be improved through the following techniques. Higher graphene absorption for the photodetector device 102 can be achieved by extending the graphene layer 131 length and by coupling the graphene layer 131 with a transverse magnetic (TM) waveguide 111 mode with a stronger evanescent field. Additionally or alternatively, the metal-doped junction(s) 125, 126 of the current photodetector can give rise to an internal quantum efficiency as high as 3.8% at zero V_{B}. This efficiency could be improved (e.g., by up to 15-30%) by electrically gating the graphene layer to reshape the depth and location of the potential difference, as described herein. Additionally or alternatively, the metal electrode(s) 121, 122 used to dope the metal-graphene junction(s) 125, 126 to couple with the evanescent field of the waveguide 111 can be evaporated to be thinner, which can dope the graphene efficiently with lower light absorption into the metal electrode(s) 121, 122. For example, and as embodied herein, a strong photoresponse can be achieved for the detector device 102, which can be reliable for realistic photonic applications even at zero bias. Moreover, the device 102 can work with an ultrafast dynamic response at zero-bias operation, for example, which can allow low on-chip power consumption. In some embodiments, the device 102 can be fabricated with silicon nitride couplers 152, which can show 3 dB fiber-to-waveguide coupling loss. The silicon nitride couplers 152 can enable the high-temperature processing as part of the CMOS process, and high-temperature annealing can be compatible with graphene. In addition, planarization of the photonic integrated circuit can enable reliable transfer of wafer-scale graphene with a low probability of rupture and/or growth of graphene directly on an entire chip. Therefore, the CMOS-processing compatibility of waveguide-integrated graphene photodetector devices 100, 101, 102 can occur through (1) the use of chemical vapor deposition grown graphene, either transferred or selectively grown on the waveguide 111 chip, and/or (2) deposition of CMOS-compatible metal to replace gold in the titanium/gold electrodes 121, 122. A waveguide-integrated graphene photodetector device 102, which can have a compact footprint, zero-bias operation and ultrafast responsivity over a broad spectral range, can enable high-performance, CMOS-compatible graphene optoelectronic devices in photonic integrated circuits. For example, and as embodied herein, an exemplary photodetector device 102 can achieve a photoresponsivity exceeding 0.1 A W¹, a nearly uniform response between 1450 and 1590 nm, response rates exceeding 20 GHz, and/or a 12 Gbit s⁻¹ optical data link under zero-bias operation.

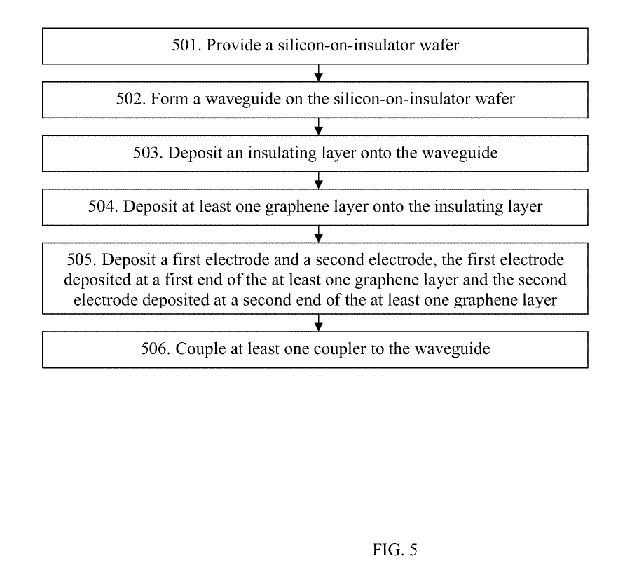

In another aspect of the disclosed subject matter, FIG. 5 shows a flowchart of an exemplary method for making a device for detecting photons, in accordance with some embodiments of the disclosed subject matter. At 501, a silicon-on-insulator (SOI) wafer can be provided. For purpose of illustration and not limitation the silicon-on-insulator wafer can be a silicon layer disposed on a buried oxide (BOX) layer. For example, the BOX layer can be a layer of silicon dioxide, hafnium oxide, or any other suitable oxide. Alternatively, this insulator layer can be a layer of boron nitride or any other suitable dielectric material. This layer can have any suitable thickness, for example, a thickness of 2 μm. Additionally, the silicon layer can have any suitable thickness, as described above regarding waveguide 111. For example, the silicon layer can have a thickness of 220 nm. Alternatively, this layer can be a layer of any suitable material for making an optical waveguide, as described above regarding waveguide 111.

At 502, a waveguide 111 can be formed on the silicon-on-insulator wafer. For purpose of illustration and not limitation, a waveguide 111 can be formed on the silicon-on-insulator wafer by any suitable lithography techniques and/or etching techniques. For example, a waveguide 111 can be formed using a combination of electron beam lithography and inductively coupled plasma (ICP) dry etching. The waveguide 111 can have any suitable dimensions, as described herein. For purpose of illustration and not limitation, a silicon bus waveguide 111 can be fabricated on the silicon-on-insulator wafer with a cross-section of 220 nm by 520 nm, which can confine light in a sub-wavelength dimension and can ensure a single confined transversal electrical mode with low scattering loss along the waveguide 111.

Alternatively, for purpose of illustration and not limitation, the silicon waveguide(s) 111 can be fabricated on an SOI wafer with a 220-nm-thick silicon membrane over a 3-μm-thick SiO₂ film using the standard shallow trench isolation (STI) module in CMOS processing. The waveguide 111 can have any suitable width, for example, a width of 520 nm to ensure a single TE mode with low transmission loss in the waveguide 111.

At 503, an insulating layer 141 can be deposited onto the waveguide. For purpose of illustration and not limitation, the insulating layer 141 can be deposited onto the waveguide 111 and the silicon-on-insulator wafer. In some embodiments, the insulating layer 141 can be planarized, as described below. For example, the insulating layer 141 can be planarized by chemical mechanical polishing (CMP).

For purpose of illustration and not limitation, the insulating layer 141 can be planarized to avoid fragmentation or rupturing of the graphene layer 131 on the edge(s) of waveguide(s) 111. For example, a silicon dioxide layer can remain after the planarization process to electrically isolate the graphene layer 131 from the silicon waveguide 111. The insulating layer 141 can have any suitable dimensions, as described herein. For example, the insulating layer 141 can have a thickness of about 10 nm.

For purpose of illustration and not limitation, the insulating layer 141 can be planarized by depositing or backfilling a thick layer of insulating material, for example, silicon dioxide (SiO₂), layer and then removing at least a portion of the insulating material to provide a smooth, planar surface using any suitable process, for example, a chemical mechanical polishing (CMP) process. The insulating layer 141 that remains after the removal can have any suitable thickness, as described herein. For example, an SiO₂ insulating layer 141 can have a thickness of about 10 nm to ensure the electrical isolation of the graphene layer(s) 131 from the silicon waveguide 111.

Alternatively, the insulating layer 141 can be planarized by backfilling the SOI wafer with a thick SiO₂ layer and chemical mechanical polishing the SiO₂ layer to a thickness that is even with the top surface of the silicon waveguide 111. The insulation layer 141 can be deposited on the waveguide 111 and backfilled SiO₂ layer to ensure electrical isolation of the graphene layer 131 from the waveguide 111. For example, the insulation layer 141 can be an about 10-nm-thick SiO₂ layer.

At 504, at least one graphene layer 131 can be deposited onto the insulating layer. For purpose of illustration and not limitation, a single layer of graphene can be deposited. Additionally or alternatively, a graphene bi-layer 131 can be deposited. For example, a mechanically exfoliated graphene bi-layer can be deposited using a precise transfer technique, as described herein. Additionally or alternatively, the number of layers of graphene can be confirmed by a Raman spectroscopy. The graphene layer 131 can absorb light from the waveguide 111 by coupling with the evanescent field of the waveguide mode and generating photocarriers, as described herein.

At 505, a first electrode and a second electrode can be deposited. The first electrode can be deposited at a first end of the graphene layer(s) 131, and the second electrode can be deposited at a second end of the graphene layer(s) 131. For purpose of illustration and not limitation, one of the electrodes 121, 122 can be closer to the waveguide 111 to efficiently separate the photon-excited electron-hole pairs and form the photocurrent on graphene layer 131, as described herein. Due to the metal-doping of the graphene layer 131 at the junctions 125, 126, there can be a potential difference at the metal/graphene interface, and the potential difference can establish an internal electric field along the graphene layer 131 and overlaps with the generated photocarriers. The photocurrent of the separated photocarriers can be measured using the two electrodes 121, 122.

For purpose of illustration and not limitation, a first resist can be deposited at the first end of the graphene layer(s) 131, and a second resist can be deposited at the second end of the graphene layer(s) 131. A shape of the first electrode 121 can be defined in the first resist, and a shape of the second electrode 122 can be defined in the second resist. At least one layer of metal can be deposited into the first resist to form the first electrode 121, and at least one layer of metal can be deposited into the second resist to form the second electrode 122. The first and second resists can be removed after the electrodes 121, 122 are deposited.

For example, as embodied herein, the patterns of the metal electrodes 121, 122 can be defined in a poly(methyl methacrylate) (PMMA) resist using any suitable lithography technique, for example, electron beam lithography, which can support a precise alignment with a resolution smaller than 20 nm, for example, about 10 nm. At least one metal layer can be deposited into the resist. For example, a titanium (Ti) layer having a first thickness, e.g., 1 nm, can be deposited using electron-beam evaporation, and then a gold (Au) layer having a second thickness, e.g., 40 nm, can be deposited using electron-beam evaporation. Thus, titanium/gold (Ti/Au) 1 nm/40 nm metal electrodes 121, 122 can be deposited, and the resist can be lifted off. One of the electrodes 121, 122 can be designed to be, for example, about 100 nm from the waveguide 111 to implement the photodetection with zero-bias operation, as described herein.

For purpose of illustration and not limitation, second electrode 122 and first electrode 121 can be created by liftoff patterning with separations of 100 nm and 3.5 μm from the edges of the waveguide 111, respectively. Thus, in some embodiments, the fabrication of an exemplary waveguide-integrated graphene photodetector device 102 can use two lithography procedures and no need for implantation, making this fabrication simpler than certain heterogeneous integration of other semiconductors.

At 506, in some embodiments, at least one coupler 152 can be coupled to the waveguide 111. The coupler can be any suitable coupler as described herein, including but not limited to an optical fiber, a lensed optical fiber, a lens, or a butt-coupler to the waveguide. For purpose of illustration and not limitation, a butt-coupler can be fabricated on at least one end of the waveguide. For example, couplers made of any suitable polymer, e.g., SU8, can be fabricated at the both ends of the silicon waveguide 111 to help the coupling of the light.

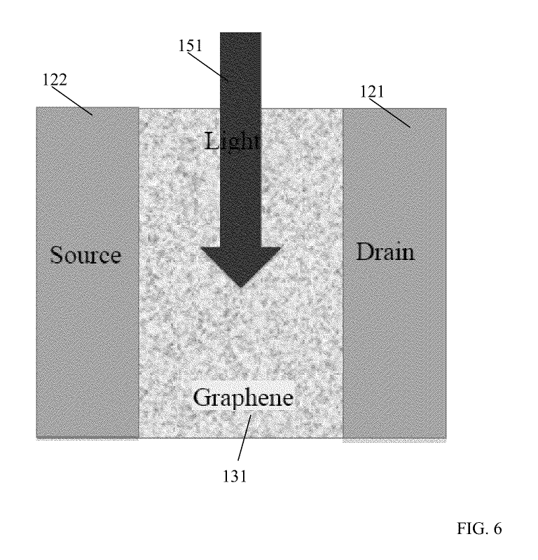

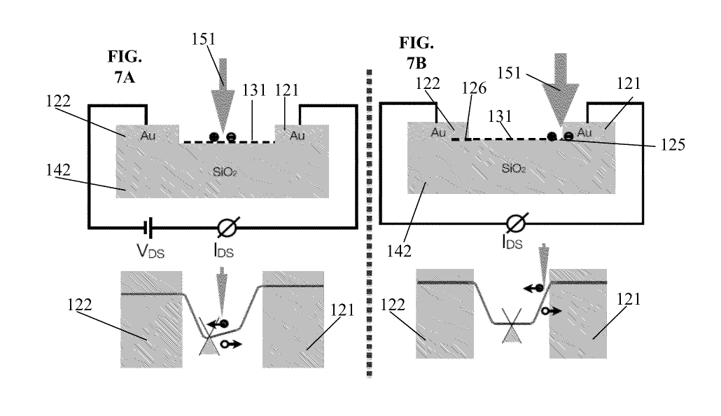

FIG. 6 shows a diagram of an exemplary graphene photodetector, in accordance with some embodiments of the disclosed subject matter. A graphene photodetector can be fabricated as described above. Additionally or alternatively, a graphene photodetector can be fabricated by electrically contacting the graphene layer 131 with a source electrode 122 and a drain electrode 121. Light absorbed in the graphene layer 131 can generate electron and hole pairs, which can be separated by a potential difference across the graphene layer 131.

FIGS. 7A and 7B show diagrams of potential difference across exemplary graphene photodetectors, in accordance with some embodiments of the disclosed subject matter. A potential difference can be created by an external electric field through a source-drain bias, as shown in FIG. 7A. Additionally or alternatively, a potential difference can be created by an internal electric field formed due to different doping levels between the graphene layer 131 and the metal-doped junctions 125, 126, as shown in FIG. 7B. In some embodiments, the internal electric field can be further enhanced by externally gating the graphene layer, as described herein.

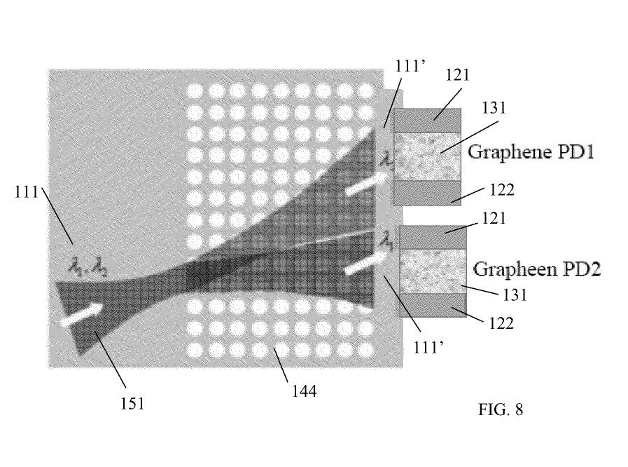

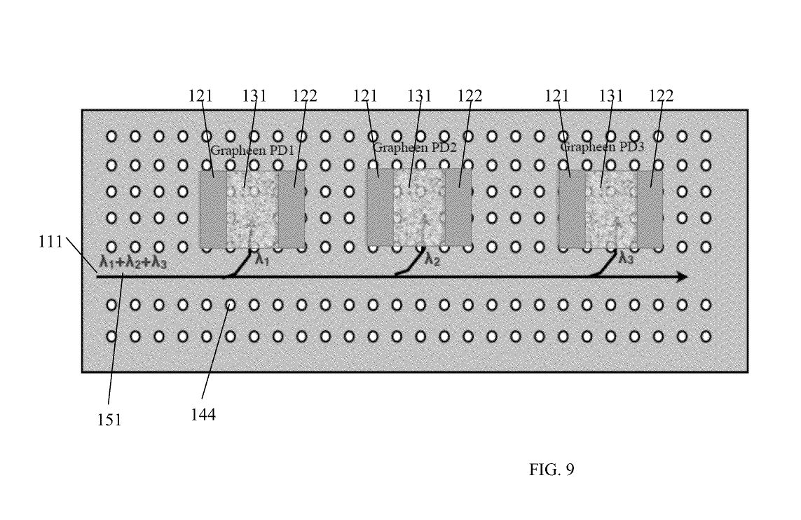

In another aspect of the disclosed subject matter, FIGS. 8 and 9 show diagrams of exemplary devices for spectroscopy, in accordance with some embodiments of the disclosed subject matter. A device for spectroscopy can include at least one input waveguide 111. The waveguide 111 can be any suitable waveguide, including a single mode waveguide, a multimode waveguide, a one-dimensional waveguide, and/or a two-dimensional waveguide. For purpose of illustration and not limitation, the waveguide 111 can be a two-dimensional, multimode waveguide 111. In some embodiments, the waveguide 111 can be integrated onto a photonic integrated circuit (PIC).

At least one coupler 152 can be coupled to the at least one input waveguide. The coupler(s) 152 can be any suitable coupler, as described herein, including but not limited to an optical fiber, a lensed optical fiber, a lens, an edge coupler, a evanescent coupler, a grating coupler, and/or a butt-coupler. The coupler 152 can couple light 151, for example, infrared and/or visible light, into the waveguide 111.

A spectral separation mechanism 144 can be coupled to the input waveguide 111 to separate the spectral components of electromagnetic radiation. For purpose of illustration and not limitation, a spectral selection mechanism can direct at least one selected frequency component of the electromagnetic spectrum to a graphene photodetector. The spectral separation mechanism 144 can be any suitable mechanism for separating electromagnetic radiation into spectral components, including but not limited to a superprism, a drop-cavity filter, and/or an echelle grating. For example, the light in the waveguide 111 can be de-multiplexed using one or a combination of these spectral separation techniques. The spectral components of the input light 151 thus can be spatially separated to a set of waveguide modes.

A plurality of photodetectors can be disposed proximate to the spectral separation mechanism 144, and each photodetector can detect a respective selected frequency component of electromagnetic radiation. Additionally, and as embodied herein, and each of the photodetectors can have at least one graphene layer 131 as the photodetecting layer. Any suitable number of photodetectors can be used, and the photodetectors can be arranged in any suitable manner, including but not limited to a one-dimensional array or a two-dimensional array.

For purpose of illustration and not limitation, an array of graphene photodetectors can be coupled to these separated waveguide modes and can convert the optical intensities into photocurrents to yield the de-multiplexed detected spectrum. FIGS. 8 and 9 show diagrams of exemplary on-chip graphene spectrometers. Referring to FIG. 8, the spectral selection mechanism 144 can be a photonic crystal (PC) superprism 144. The superprism 144 can split the input light 151 into different channels with different wavelengths corresponding to monochromatic optical modes. The inherent optical absorption in graphene can be weak. In some embodiments, techniques such as waveguide-integration, slow light, and optical cavity techniques can increase the absorption coefficient of graphene photodetectors. For purpose of illustration and not limitation, each monochromatic mode can couple into a corresponding waveguide 111′, and each graphene photodetector can be integrated on to a corresponding waveguide 111′, as described herein. In some embodiments, a plurality of waveguides 111′ can be coupled to the superprism 144, and each of the waveguides 111′ can direct the respective selected frequency component or wavelength of electromagnetic radiation to each of the photodetectors. In some embodiments, the respective selected frequency component or wavelength of electromagnetic radiation of each of the photodetectors can be different than the respective selected frequency component or wavelength of electromagnetic radiation of each of the other photodetectors. For example, and not limitation, a first graphene photodetector PD1 can be coupled to a first corresponding waveguide 111′ to detect a certain wavelength λ₂, a second graphene photodetector PD2 can be coupled to a second corresponding waveguide 111′ to detect a certain wavelength λ₁. Additionally or alternatively, more photodetectors and corresponding waveguides can be employed to detect more wavelengths. This waveguide-integration can enhance the graphene photodetection, as described herein. The photocurrent can create electrical signals on the graphene detector(s) PD1, PD2, and the electrical signals corresponding to each wavelength λ₁, λ₂ can be used to indicate the intensities of each wavelength across the spectrum of the light.

Referring to FIG. 9, the spectral selection mechanism 144 can be one or more photonic crystal drop cavity filters 144, for example, a plurality of drop-cavity filters 144. Input light 151 can be filtered into the drop-cavities 144 with a very high resolution, for example, a resolution up to 0.02 nm. Graphene photodetectors each can be integrated onto a respective one of the drop-cavities 144 corresponding to the respective selected frequency component or wavelength of electromagnetic radiation thereof. For example, and not limitation, a first graphene photodetector PD1 can be integrated onto a first drop-cavity 144 to detect light having a first wavelength λ₁, a second graphene photodetector PD2 can be integrated onto a second drop-cavity 144 to detect light having a second wavelength λ₂, and a third graphene photodetector PD3 can be integrated onto a third drop-cavity 144 to detect light having a third wavelength λ₃. Additionally or alternatively, more photodetectors and corresponding drop-cavities 144 can be employed to detect more wavelengths. The graphene photodetectors PD1, PD2, PD3 can absorb the respective wavelengths λ₁, λ₂, λ₃ of the input light 151 in each cavity with nearly 100% efficiency, for example, an efficiency of about 85-100%, which can depend on the coupling between graphene layer(s) 131 and the drop-cavity 144 and can be due at least in part to cavity enhancement, which can result in a high-performance graphene spectrometer.

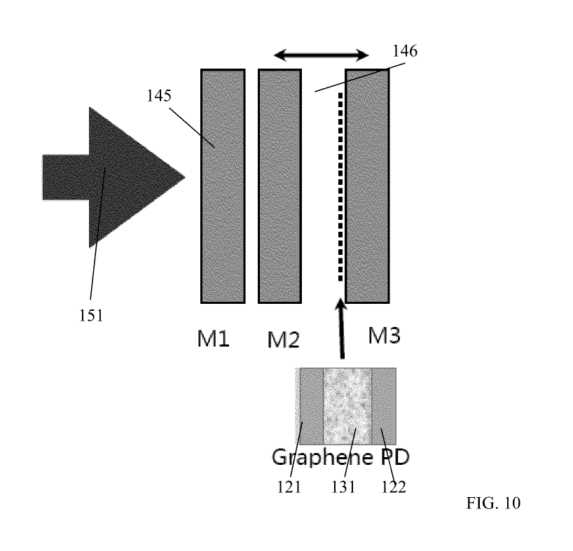

FIG. 10 shows a diagram of an exemplary device for detecting a selected wavelength of electromagnetic radiation, in accordance with some embodiments of the disclosed subject matter. A scannable interface filter 145 can have at least one cavity 146, and the cavity 146 can have a resonant wavelength to match a selected wavelength or frequency of input electromagnetic radiation 151. The filter 145 can include two or more mirrors. For example, a two-mirror filter can be similar to a Fabry Perot (FP) cavity. Alternatively, a filter 145 of more than two mirrors can enable greater control of the allowed transmission of input light 151 to the last cavity 146. In some embodiments, at least one graphene photodetector can be located in the last cavity 146. For example, at least one graphene photodetector PD can be disposed within at least one cavity 146, such as the last cavity 146. The photodetector PD can have graphene as the photodetecting layer and can detect the selected wavelength of electromagnetic radiation 151. The graphene photodetector can include one or more graphene layers 131 contacted to a source electrode 122 and a drain electrode 121, as described herein.

The device can further include an actuation mechanism connected to the scannable interface filter 145 to adjust the resonant wavelength of the cavity 146. For example, the actuation mechanism can include at least one of a piezoelectric actuation mechanisms, a static electric actuation mechanisms, and/or an electrostrictive actuation mechanism. For purpose of illustration and not limitation, the mirrors can be moved to control the admission of light 151 into the last cavity 146, where a selected wavelength or frequency component of light 151 can be absorbed by graphene photodetector PD. The light absorption on the graphene layer 131 can be enhanced at the resonant wavelength of the cavity 146. In some embodiments, the graphene photodetector can detect only the wavelength or frequency component of light 151 on resonance in the cavity 146, showing a selectivity of the highly resolved wavelength. For example, the resolution of a spectrometer device can be determined by the linewidth of the FP cavity 146. The absorption efficiency can approach 100%, for example, an efficiency of between 50-100%, in a single-sided device where the reflectivity of the last mirror of the last cavity 146 can be higher than that of the preceding mirrors. The selected wavelength can be measured by scanning the scannable interface filter 145, which can be calibrated by the resonant wavelength of the cavity 146 on the graphene photodetector PD.

For purpose of illustration and not limitation, the scannable interface filter 145 can include a first mirror M3 having a first reflectivity and a second mirror M2 having a second reflectivity. The at least one cavity 146 can be between the first mirror M3 and second mirror M2, and the first reflectivity can be greater than the second reflectivity. In some embodiments, the scannable interface filter 145 can further include at least one further mirror M1. A further cavity 146 can be between the second mirror M2 and the further mirror M1. Additionally or alternatively, the scannable interface filter 145 can include a plurality of mirrors. A further cavity 146 can be between the second mirror M2 and the plurality of mirrors, and the plurality of mirrors can include a plurality of cavities 146 between successive ones of the plurality of mirrors.

Additionally, in some embodiments, the device can include a two-dimensional array of graphene photodetectors in the cavity 146, for example, located on the surface of the last mirror. This array of photodetectors can be used for hyperspectral imaging. For purpose of illustration and not limitation, a scene can be imaged on the interference filter 145, and the filter 145 can be scanned to determine the spectral information at each photodetector, where each photodetector can correspond to a point (x, y) of the scene.

The graphene photodetector can perform better than certain photodetectors, as described herein. For purpose of illustration and not limitation, a graphene photodetector can be ultrafast, for example, capable of operating at hundreds of GHz, compared to tens of GHz in certain other photodetectors. Additionally, graphene photodetectors can also be cheaper and easier to fabricate than certain other photodetectors, as described herein, and graphene photodetectors can be flexible. Further, graphene photodetectors can detect light or electromagnetic radiation over a broad band of the spectrum, as described herein. Additionally, the absorption line of a graphene photodetector can be reduced with respect to different input wavelengths. This can allow graphene photodetectors to achieve spectrally-resolved photodetection.

Referring to FIGS. 11-12C, an exemplary device for detecting photons can include at least one graphene layer 131. A source electrode 122 can be connected to a first end of the at least one graphene layer 131, and a drain electrode 121 can be connected to a second end of the at least one graphene layer opposite the first end. A gate electrode 123 can be disposed proximate to the at least one graphene layer. In some embodiments, the gate electrode 123 can be positioned so as not to electrically contact the graphene layer 131. In some embodiments, the gate electrode 123 can be embedded in the substrate 142. Additionally or alternatively, at least part of the substrate 142 can be conductive, and the substrate 142 can act as the gate electrode 123. Additionally or alternatively, at least part of a waveguide 111 can be doped to be slightly conductive, and the waveguide 111 can be used as the gate electrode 123. Voltage can be supplied to the doped waveguide 111 to apply an electric field across the graphene layer 131. In some embodiments, the doping of the waveguide can be small enough so that the absorption in the doped section of the waveguide 111 can be negligible, for example, a doping of less than 10¹⁸ cm⁻³. Additionally or alternatively, the gate electrode 123 can include a transparent, conductive layer disposed above or below the graphene layer 131. The transparent, conductive layer can apply a vertical electric field across the graphene layer 131.

A voltage source can be connected to the gate electrode 123 and can modulate a Fermi energy E_{G} of the graphene layer 131 to block absorption of a selected frequency ω of electromagnetic radiation. For example, the voltage on the gate electrode 123 can induce an optical transparency in the graphene layer 131. Absorption of light in the graphene layer 131 can be blocked by tuning the Fermi energy (E_{G}).

For purpose of illustration and not limitation, for light with frequency of ω, the Fermi energy E_{G} of the graphene layer 131 can be tuned by hω/2 away from the Dirac point of the graphene, for example, E_{G}>hω/2, and the absorption on the graphene layer 131 of light with this wavelength ω can be Pauli blocked. For example, no photocurrent can be detected on the graphene photodetector at the optical frequency of ω. Thus, absorption and photocurrent generation can be varied with respect to a gate voltage-controlled Fermi energy E_{G}. As a graphene spectrometer, the electrical gating voltage can be scanned on the graphene layer 131 and tune E_{G}. The photocurrent I(E_{G}) can be recorded as a function of the gate voltage-controlled Fermi energy E_{G}. The current can be given by:

$$I ( {E}_{G} ) = {\int }_{ω ( {E}_{G} )}^{∞} \frac{P ( ω )}{ℏ ω} η ( ω ) d ω ,$$

where P(ω) can be the incident power spectrum of light with frequency ω and η(ω) can be the photocurrent conversion coefficient, which can be proportional to ω because of carrier multiplication in graphene and/or can be assumed to be known or calibrated. P(ω) can be calculated, for example, using the first fundamental theorem of calculus: differentiating I(E_{G}) with respect to ω(E_{G}). Due to the uniquely high Fermi velocity on graphene [How high is it? Can you compare it to other materials?], the Fermi energy E_{G} of graphene can be tuned to be higher than 1 eV, which can corresponds to an optical tunability up to the visible spectrum.

In some embodiments, a waveguide 111 can be disposed proximate to the graphene layer 131 and can direct electromagnetic radiation to the at least one graphene layer, as described herein. The graphene layer 131 can strongly couple with the evanescent field of the waveguide mode and can produce electron-hole pairs for photocurrent because of enhanced absorption on graphene layer 131, as described herein. In some embodiments, an insulating layer can be disposed between the waveguide 111 and the graphene layer 131. Additionally or alternatively, other geometries can be employed to improve this gated graphene spectrometer device in both the planar PIC and the free-space interference filter architectures, for example, as described with regard to FIGS. 8-10. For example, the device can include a spectral selection 144 and/or a scannable interface filter 145, as described herein.

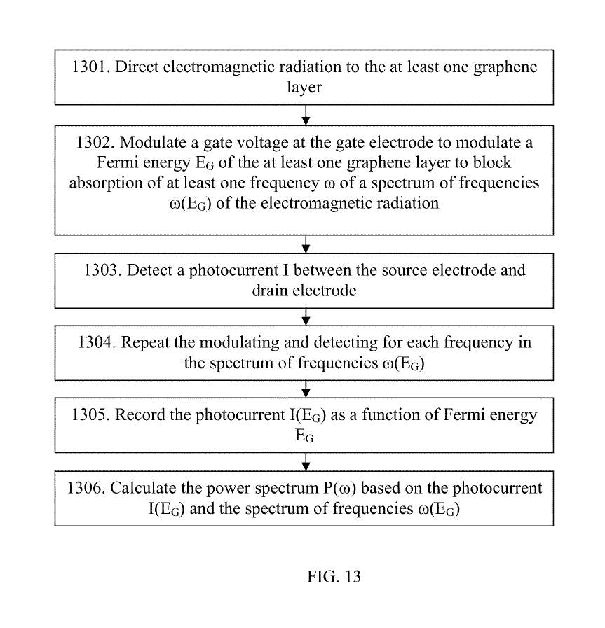

FIG. 13 shows a flowchart of an exemplary method for detecting electromagnetic radiation, in accordance with some embodiments of the disclosed subject matter. For purpose of illustration and not limitation, a device for detecting photons can have at least one graphene layer 131, a source electrode 122 connected to a first end of the at least one graphene layer 131, a drain electrode 121 connected to a second end of the at least one graphene layer 131 opposite the first end, and a gate electrode 123 proximate to the at least one graphene layer 131. At 1301, electromagnetic radiation can be directed to the at least one graphene layer 131. At 1302, a gate voltage can be modulate at the gate electrode 123 to modulate a Fermi energy E_{G} of the graphene layer 131 to block absorption of at least one frequency ω of a spectrum of frequencies ω(E_{G}) of the electromagnetic radiation. At 1303, A photocurrent I can be detected between the source electrode 122 and drain electrode 121. For example, the gate voltage can be modulated to modulate the Fermi energy E_{G} to greater than hω/2.

Additionally, at 1304, the modulating (1302) and detecting (1303) can be repeated for each frequency in the spectrum of frequencies ω(EG). At 1305, the photocurrent I(E_{G}) can be recorded as a function of Fermi energy E_{G}. Additionally or alternatively, the power spectrum P(ω) can be calculated based on the photocurrent I(E_{G}) and the spectrum of frequencies ω(E_{G}).

For purpose of illustration and not limitation, on-chip integrated graphene photodetectors can replace certain on-chip photodetectors, such as silicon-germanium (SiGe). For example, graphene photodetectors can be superior in consideration of cost, manufacturing stability, and high speed compared to these other on-chip photodetectors. Unlike certain photodetectors, graphene photodetectors can be made transparent. Such a transparent photodetector (or an array of such transparent photodetectors, e.g., for a camera) can have extensive applications for imaging and sensing components.

Additionally or alternatively, a graphene photodetector can be flexible. For example, such a photodetector can be fabricated on a curved surface. Certain cameras can be two-dimensional, while a camera made of graphene photodetectors on a curved surface can be three dimensional, which can be similar to the retina of human beings and can produce images closer to what a human brain perceives.

Additionally or alternatively, graphene can be a biocompatible material. For example, graphene photodetectors can be used to probe photoluminescence, absorption, and/or photochemical reactions in cells, tissues, or other biological systems in nanometer scale. This concept can be applied to a variety of functions, such as bio-sensing, environment monitoring, and/or clinical implanting devices.

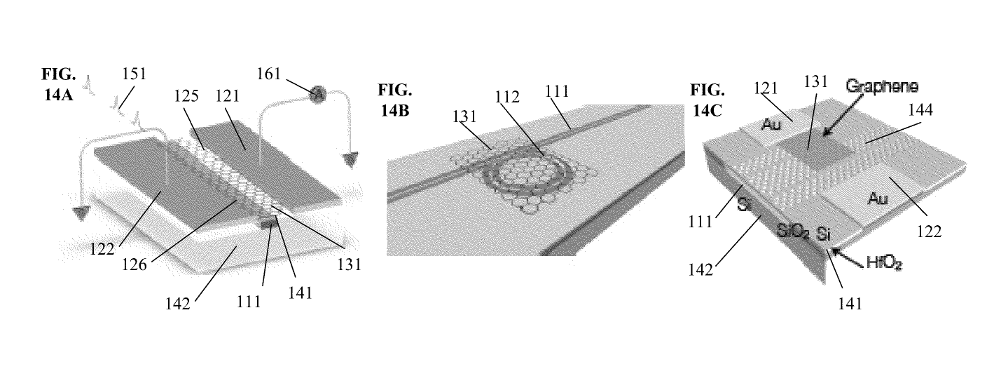

FIG. 14A shows a diagram of an exemplary device for detecting photons, in accordance with some embodiments of the disclosed subject matter. For purpose of illustration and not limitation, a silicon bus waveguide 111 with cross-section of 220 nm by 520 nm can be fabricated on a SOI wafer and then planarized using an SiO₂ insulating layer 141, as described herein. A graphene layer 131 can be disposed proximate to the waveguide 111, separated by the insulating layer 141, which can have a thickness of about 10 nm, as described herein. Two metal electrodes 121, 122 can contact the graphene layer 131 and conduct the generated photocurrent, as described herein. One of the electrodes, for example, the second electrode 122, can be closer to the waveguide 111 to create a potential difference on the graphene layer 131 coupling with the evanescent field of the waveguide 111 to enable ultrafast and efficient photodetection, as described herein.

FIG. 14B shows a diagram of an exemplary ring-oscillator integrated graphene photodetector and modulator architecture, in accordance with some embodiments of the disclosed subject matter. For purpose of illustration and not limitation, at least one graphene layer 131 can be disposed proximate to a ring-oscillator 112. A silicon ring resonator 112 can be disposed on a silicon-on-insulator substrate, as described herein. The ring resonator 112 can be coupled by a straight waveguide 111 on at least one side of the ring. Inside the resonator 112, the optical field can be enhanced, for example, by a factor of 10 thousand times. A layer of graphene 131 can be deposited on or proximate to the ring resonator 112.

FIG. 14C shows a diagram of a photonic crystal modulator and photodetector architecture, in accordance with some embodiments of the disclosed subject matter. For purpose of illustration and not limitation, an insulating layer 141, such as a layer of hafnium oxide (HfO₂), can be disposed on a waveguide 111, as described herein. A photonic crystal modulator 144 can be disposed on the insulating layer 141. A graphene layer 131 can be integrated onto the modulator 144 proximate to the waveguide 111. Two metal electrodes 121, 122 can contact the graphene layer 131 and conduct the generated photocurrent, as described herein. One of the electrodes, for example, the first electrode 121, can be closer to the waveguide 111 to create a potential difference on the graphene layer 131 coupling with the evanescent field of the waveguide 111 to enable ultrafast and efficient photodetection, as described herein.

The integration of graphene with nano-photonic architectures, such as the architectures shown in FIGS. 14A-C, can enable compact, energy-efficient, and ultrafast electro-optic graphene devices for on-chip optical communications, as described herein. For purpose of illustration and not limitation, optical links to and on silicon processing chips can be developed to address a bottleneck at the interconnects between electrical and optical devices. For example, the transmitters and receivers can be positioned directly on the silicon processors, which can be achieved by integration of optical interconnects with metal-oxide semiconductor (CMOS) technology. While certain materials, such as silicon, can be used for passive optical components, such as waveguides and multiplexing/de-multiplexing (mux/demux), such materials can present challenges for implementing suitable modulators and detectors. For example, silicon-based injection/depletion modulators can have high speed, but they can be highly sensitive to temperature fluctuations and can require active stabilization because high-Q resonator designs can reduce energy consumption. Germanium or compound semiconductors can be employed as detectors, but these materials can be complex and expensive to integrate with silicon technology.

As described herein, graphene has certain electro-optic properties, including but not limited to ultra-fast response across a broad spectrum, strong electron-electron interaction, and photocarrier multiplication. Additionally, graphene can have high-contrast (e.g., greater than 11 dB) electro-optic modulation and ultra-fast photodetection using a graphene photovoltaic detector integrated on a silicon waveguide, as described herein. Graphene can be used to develop fully CMOS-compatible technology to integrate high-performance graphene modulators and detectors on silicon CMOS processors. Due to the ultra-fast carrier dynamic and ultra high carrier saturation velocity (e.g., 5×10⁷ cm/s) for carriers in graphene, the bandwidth of graphene photodetector and modulators can be limited by the resistor-capacitor (RC) time constant at the metal-doped junctions 125, 126 where the graphene layer 131 contacts the metal electrodes 121, 122, and can exceed 500 GHz. Leveraging precise control of light-matter interaction in silicon waveguides and resonators in photonic integrated circuits, together with ultra-high-purity graphene-boron nitride material and assembly techniques, modulators and detectors based on graphene can match or exceed certain other modulators and detectors in certain characteristics, including but not limited to speed, power consumption, bandwidth, temperature stability, and ease of CMOS-compatible fabrication. For purpose of illustration and not limitation, a front-to-back communication system can use a graphene modulator and graphene photodetector to optically communicate at speeds in excess of 20 Gbps.

Light absorption in graphene can be modulated by electrical gating to induce Pauli blocking, as described herein. For purpose of illustration and not limitation, electro-optic modulation of a graphene-coupled photonic crystal nanocavity can have a contrast exceeding 10 dB, and the response speed can be limited by electrolyte contacts (e.g., electrodes 121, 122) below 500 kHz. This speed limitation can be overcome by replacing the electrolyte contacts with another graphene layer. Such a modulator can use a cavity-coupled graphene-boron nitride-graphene capacitor, as described herein with reference to FIG. 12. This modulator can have a modulation speed up to 0.57 GHz, which can be limited by the stray capacitance and resistance of the metal contact.

For purpose of illustration and not limitation, an exemplary graphene-based modulator design can achieve high contrast, for example, greater than 10 dB, and fast operation, for example, greater than 12 Gbps, using sub-micron scale contact electrodes with low resistance. Referring to FIG. 14A, an exemplary silicon-on-insulator (SOI) waveguide-integrated design can offer broad-band modulation, as described herein. Referring to FIG. 14B, an exemplary SOI micro-ring architecture can offers spectrally selective modulation of desired spectral channels. Referring to FIG. 14C, an exemplary photonic crystal-design cab enable an exceptionally small footprint, for example, about 5 μm×5 μm, which can enable ultra-fast operation in excess of 20 GHz and ultra-low power consumption below 1 fJ/bit. Leveraging integrated optical circuits coupled with CMOS logic, fully integrated modulators with insertion loss below 1 dB can be developed.

For purpose of illustration and not limitation, graphene photodetectors can have certain electro-optical properties, as described herein, including strong electron-electron interaction in graphene to enable the generation of multiple electron-hole pairs for a single incident photon, even under zero external bias; the zero-bandgap nature of graphene to enable an ultra-wide absorption spectrum; and the fast carrier dynamics to enable response speed of hundreds of GHz. However, a remaining problem concerns the limited optical absorption in graphene, which results in a low optical responsivity. The performance of graphene photodetectors can be improved by integration in CMOS. For example, these detectors can be integrated directly on-chip with CMOS transimpedance amplifiers. To reduce the length of an exemplary graphene photodetector, for example, from 40 μm to less than 10 μm, the graphene optical absorption can be enhanced by increasing the overlap and/or interaction between light and a graphene layer 131. For example, and not limitation, silicon slot waveguides and/or slow-light waveguides can employ photonic crystal structures to increase the interaction between light and the graphene layer 131. Additionally or alternatively, an asymmetric metal electrode design of titanium gold (Ti/Au) can be implemented to reduce absorption by the metal contact electrode(s) while enhancing the induced electric field across the inherent electric field for efficient carrier separation. The dependence of the carrier multiplication factor M on device geometry can also be characterized and enhanced. The encapsulation in BN, electrical gating, and/or bias dependence can affect the graphene photodetector performance, as described herein.

For purpose of illustration and not limitation, graphene photodetector devices can detect light or electromagnetic radiation with wavelengths from the infrared to beyond 2 μm at response speeds in excess of 60 GHz. Additionally or alternatively, silicon nitride (SiN) waveguide edge-coupling can achieve efficient 3 dB fiber-to-waveguide coupling loss and can ensure compatibility with the high-temperature CMOS processing. By enhancing the absorption of light, photocarrier multiplication, and photocarrier collection, the absorptivity of graphene photodetectors can be increased by more than a factor of six to nearly 0.7 A/W.

The foregoing merely illustrates the principles of the disclosed subject matter Various modifications and alterations to the described embodiments will be apparent to those skilled in the art in view of the teachings herein. It will thus be appreciated that those skilled in the art will be able to devise numerous techniques which, although not explicitly described herein, embody the principles of the disclosed subject matter and are thus within its spirit and scope.

What is claimed is:

1. A device for detecting photons, comprising:
a waveguide;
at least one graphene layer disposed proximate to the waveguide and adapted to be connected to a first electrode at a first end of the at least one graphene layer and a second electrode at a second end of the at least one graphene layer opposite the first end; and
an insulating layer disposed between the waveguide and the at least one graphene layer.

2. The device of claim 1, the waveguide comprising a silicon waveguide.

3. The device of claim 2, the silicon waveguide having a cross-section of 220 nm by 520 nm.

4. The device of claim 1, the insulating layer comprising one of a silicon dioxide layer, a boron nitride layer, or a hafnium oxide layer.

5. The device of claim 4, the insulating layer comprising a silicon dioxide layer having a thickness of 10 nm.

6. The device of claim 1, the at least one graphene layer comprising a graphene bi-layer.

7. The device of claim 1, the first electrode being a first distance from the waveguide and the second electrode being a second distance from the waveguide, wherein the second distance is less than the first distance.

8. The device of claim 7, the at least one graphene layer comprising a metal-doped junction proximate to the second electrode.

9. The device of claim 1, the first electrode and second electrode each comprising a titanium/gold ( 1/40 nm) metal electrode.

10. The device of claim 1, further comprising at least one of a voltage source connected to the first electrode or a current source connected to the first electrode.

11. The device of claim 1, further comprising a light source coupled to the waveguide.

12. The device of claim 11, the light source comprising a laser having a wavelength of 1450-1590 nm.

13. The device of claim 1, further comprising at least one coupler coupled to the waveguide.

14. The device of claim 13, the at least one coupler comprising at least one of an optical fiber, a lensed optical fiber, a lens, an edge coupler, a evanescent coupler, a grating coupler, or a butt-coupler.

15. The device of claim 1, further comprising a spectral selection mechanism to direct a selected frequency component of electromagnetic radiation to the at least one graphene layer.

16. The device of claim 15, wherein the spectral selection mechanism comprises at least one of a superprism, a drop-cavity filter, an echelle gratings, or a scannable interface filter.

17. The device of claim 1, further comprising:
a gate electrode proximate to the at least one graphene layer; and
a voltage source connected to the gate electrode and configured to modulate a Fermi energy E_{G} of the at least one graphene layer to block absorption of a selected frequency ω of electromagnetic radiation.

18. A method of making a device for detecting photons, comprising:
providing a silicon-on-insulator wafer;
forming a waveguide on the silicon-on-insulator wafer;
depositing an insulating layer onto the waveguide;
depositing at least one graphene layer onto the insulating layer; and
depositing a first electrode and a second electrode, the first electrode deposited at a first end of the at least one graphene layer and the second electrode deposited at a second end of the at least one graphene layer.

19. The method of claim 18, the forming the waveguide comprising forming a waveguide on the silicon-on-insulator wafer by at least one of electron beam lithography and inductively coupled plasma (ICP) dry etching.

20. The method of claim 18, further comprising coupling at least one of an optical fiber, a lensed optical fiber, a lens, or a butt-coupler to the waveguide.

21. The method of claim 20, the coupling comprising fabricating a butt-coupler on at least one end of the waveguide.

22. The method of claim 18, the depositing the insulating layer comprising:
depositing the insulating layer onto the waveguide and the silicon-on-insulator wafer; and
planarizing the insulating layer by chemical mechanical polishing (CMP).

23. The method of claim 18, the depositing the at least one graphene layer comprising depositing a mechanically exfoliated graphene bi-layer.

24. The method of claim 18, the depositing the first electrode and the second electrode comprising:
depositing a first resist at the first end of the at least one graphene layer and a second resist at the second end of the at least one graphene layer;
defining a shape of the first electrode in the first resist and a shape of the second electrode in the second resist;
depositing metal into the first resist to form the first electrode and into the second resist to form the second electrode; and
removing the first and second resists.

25. A device for spectroscopy, comprising:
at least one input waveguide;
at least one coupler coupled to the at least one input waveguide;
a spectral separation mechanism coupled to the at least one input waveguide to separate the spectral components of electromagnetic radiation; and
a plurality of photodetectors disposed proximate to the spectral separation mechanism, each configured to detect a respective selected frequency component of electromagnetic radiation, and each of the photodetectors having graphene as the photodetecting layer.

26. The device of claim 25, the at least one coupler comprising at least one of an optical fiber, a lensed optical fiber, a lens, an edge coupler, a evanescent coupler, a grating coupler, or a butt-coupler.

27. The device of claim 25, the spectral separation mechanism comprising at least one of a superprism, a drop-cavity filter, or an echelle grating.

28. The device of claim 25, wherein the respective selected frequency component of electromagnetic radiation of each of the photodetectors is different than the respective selected frequency component of electromagnetic radiation of each of the other photodetectors.

29. The device of claim 25, the spectral separation mechanism comprising a superprism, further comprising a plurality of waveguides coupled to the superprism, each of the plurality of waveguides configured to direct the respective selected frequency component of electromagnetic radiation to each of the photodetectors.

30. The device of claim 25, the spectral separation mechanism comprising a plurality of drop-cavity filters, and each of photodetectors integrated on a respective one of the drop-cavity filters corresponding to the respective selected frequency component of electromagnetic radiation thereof.

31. A device for detecting a selected wavelength of electromagnetic radiation, comprising:
a scannable interface filter having at least one cavity, the cavity configured to have a resonant wavelength to match the selected wavelength; and
at least one photodetector disposed within the at least one cavity, the at least one photodetector having graphene as the photodetecting layer and being configured to detect the selected wavelength of electromagnetic radiation.

32. The device of claim 31, further comprising an actuation mechanism connected to the scannable interface filter to adjust the resonant wavelength of the at least one cavity.

33. The device of claim 32, the actuation mechanism comprising at least one of a piezoelectric actuation mechanisms, a static electric actuation mechanisms, and a electrostrictive actuation mechanism.

34. The device of claim 31, the scannable interface filter comprising a first mirror having a first reflectivity and a second mirror having a second reflectivity, wherein the at least one cavity is between the first and second mirrors, and wherein the first reflectivity is greater than the second reflectivity.

35. The device of claim 34, the scannable interface filter further comprising at least one further mirror, wherein a further cavity is between the second mirror and the at least one further mirror.

36. The device of claim 34, the scannable interface filter further comprising a plurality of mirrors, wherein a further cavity is between the second mirror and the plurality of mirrors, and wherein the plurality of mirrors comprises a plurality of cavities between successive ones of the plurality of mirrors.

37. The device of claim 31, the at least one photodetector comprising a two-dimensional array of photodetectors.

38. A device for detecting photons, comprising:
at least one graphene layer adapted to be connected to a source electrode at a first end of the at least one graphene layer and a drain electrode at a second end of the at least one graphene layer opposite the first end;
a gate electrode proximate to the at least one graphene layer; and
a voltage source connected to the gate electrode and configured to modulate a Fermi energy E_{G} of the at least one graphene layer to block absorption of a selected frequency ω of electromagnetic radiation.

39. The device of claim 38, wherein the voltage source is configured to modulate the Fermi energy E_{G} to greater than hω/2.

40. The device of claim 38, further comprising a waveguide disposed proximate to the at least one graphene layer and configured to direct electromagnetic radiation to the at least one graphene layer.

41. The device of claim 40, further comprising an insulating layer disposed between the waveguide and the at least one graphene layer.

42. The device of claim 38, further comprising a spectral selection mechanism to direct a selected frequency component of electromagnetic radiation to the at least one graphene layer.

43. The device of claim 42, wherein the spectral selection mechanism comprises at least one of a superprism, a drop-cavity filter, an echelle gratings, or a scannable interface filter.

44. A method for detecting electromagnetic radiation using a device for detecting photons having at least one graphene layer, a source electrode connected to a first end of the at least one graphene layer, a drain electrode connected to a second end of the at least one graphene layer opposite the first end, a gate electrode proximate to the at least one graphene layer, the method comprising:
directing electromagnetic radiation to the at least one graphene layer;
modulating a gate voltage at the gate electrode to modulate a Fermi energy E_{G} of the at least one graphene layer to block absorption of at least one frequency ω of a spectrum of frequencies ω(E_{G}) of the electromagnetic radiation; and
detecting a photocurrent I between the source electrode and drain electrode.

45. The method of claim 44, wherein the gate voltage is modulated to modulate the Fermi energy E_{G} to greater than hω/2.

46. The method of claim 44, further comprising:
repeating the modulating and detecting for each frequency in the spectrum of frequencies ω(E_{G}); and
recording the photocurrent I(E_{G}) as a function of Fermi energy E_{G}.

47. The method of claim 46, further comprising calculating the power spectrum P(ω) based on the photocurrent I(E_{G}) and the spectrum of frequencies ω(E_{G}).
